(19) United States
(12) Patent Application Publication
(10) Pub. No.: US 2026/0133653 A1
(43) Pub. Date: May 14, 2026

(54) LG Display Co., Ltd.

(71) Applicant: LG Display Co., Ltd., Seoul (KR)

(72) Inventors: SunYeop Kim, Gyeonggi-do (KR); NamYong Gong, Gyeonggi-do (KR); SungChul Kim, Gyeonggi-do (KR); HoonBae Kim, Gyeonggi-do (KR); Sung-Jin Kang, Gyeonggi-do (KR); Jongsung Kim, Gyeonggi-do (KR)

(21) Appl. No.: 19/343,420

(22) Filed: Sep. 29, 2025

(30) Foreign Application Priority Data
Nov. 11, 2024 (KR) 10-2024-0158920

(51) Int. Cl. G06F 3/041; H01L 25/16; H10H 29/49

(52) U.S. Cl. CPC G06F 3/04164; G06F 3/0412; G06F 3/041662; G06F 3/04184; H10H 29/49; H10W 90/00

(57) ABSTRACT

A display apparatus includes: a substrate including a display area and a non-display area; a pixel driving circuit provided in the display area; first electrodes connected to the pixel driving circuit; light emitting devices provided on the first electrodes; and second electrodes provided on the light emitting devices, wherein the pixel driving circuit comprises: a sensing circuit configured to supply a cathode voltage or a touch driving signal to the second electrodes; and a sensing switch configured to, in response to a touch enable signal, transmit power from a power circuit to the sensing circuit or block power transmitted from the power circuit.

### CROSS-REFERENCE TO RELATED APPLICATIONS

Pursuant to 35 U.S.C. § 119(a), this application claims the benefit of an earlier filing date and right of priority to Korean Patent Application No. 10-2024-0158920 filed on Nov. 11, 2024 in the Republic of Korea, the entire contents of which are hereby expressly incorporated by reference into the present application.

### FIELD OF TECHNOLOGY

The present disclosure relates to a display apparatus.

### BACKGROUND

A display apparatus can be applied to various electronic devices such as TVs, mobile phones, laptops, and tablets etc.

Display apparatuses can include organic light emitting displays (OLEDs), that emit light by themselves, and liquid crystal displays (LCDs), that require separate light sources.

Recently, a display apparatus including a light emitting diode (LED) has attracted attention as a next-generation display apparatus, in which the light emitting diode is made of an inorganic material, not an organic material. Compared to liquid crystal displays or organic light emitting displays, a display apparatus including such a light emitting diode can have a faster lighting speed, can have excellent luminous efficiency, and can display an image having high luminance.

### SUMMARY

According to one aspect, there is provided a display apparatus that includes: a substrate including a display area and a non-display area; a pixel driving circuit provided in the display area; first electrodes connected to the pixel driving circuit; light emitting devices provided on the first electrodes; and second electrodes provided on the light emitting devices, wherein the pixel driving circuit includes: a sensing circuit configured to supply a cathode voltage or a touch driving signal to the second electrodes; and a sensing switch configured to, in response to a touch enable signal, transmit power from a power circuit to the sensing circuit or block power transmitted from the power circuit.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure.

FIG. 1 is a perspective view illustrating a display apparatus according to an implementation of the present disclosure;

FIG. 2 is a plan view of a display apparatus according to an implementation of the present disclosure;

FIG. 3 is an enlarged exemplary diagram of a portion of a display apparatus according to an implementation of the present disclosure;

FIG. 4 is an exemplary diagram illustrating a structure of a pixel driving circuit applied to a display apparatus according to an implementation of the present disclosure;

FIGS. 5 to 7B are plan views of a display panel applied to a display apparatus according to an implementation of the present disclosure;

FIG. 8 is an exemplary diagram illustrating a cross-sectional surface of a display panel applied to a display apparatus according to an implementation of the present disclosure;

FIG. 9 is a cross-sectional view of a light emitting device applied to a display apparatus according to an implementation of the present disclosure;

FIG. 10 is an exemplary diagram illustrating a structure of a touch electrode part and a display driver applied to a display apparatus according to an implementation of the present disclosure;

FIG. 11A is an exemplary diagram illustrating structures of a sub-touch electrode and a pixel driving circuit applied to a display apparatus according to an implementation of the present disclosure;

FIG. 11B is an exemplary diagram illustrating a connection structure of a sub-touch electrode and a pixel driving circuit applied to a display apparatus according to an implementation of the present disclosure;

FIG. 11C is an exemplary diagram illustrating a connection relationship between a pixel driving circuit and light emitting devices applied to a display apparatus according to an implementation of the present disclosure;

FIG. 11D is an exemplary diagram illustrating a light emitting signal applied to a display apparatus according to an implementation of the present disclosure;

FIG. 11E is an exemplary diagram illustrating a pixel circuit applied to a display apparatus according to an implementation of the present disclosure;

FIG. 11F is an exemplary diagram illustrating a touch sensing method in a display apparatus according to an implementation of the present disclosure;

FIG. 11G is an exemplary diagram illustrating a display period and a touch sensing period applied to a display apparatus according to an implementation of the present disclosure;

FIGS. 12A to 12E are exemplary diagrams illustrating various driving methods of a display apparatus according to an implementation of the present disclosure; and

FIGS. 13 to 16 are diagrams illustrating electronic devices to which a display apparatus according to implementations of the present disclosure is applied.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Implementations of the present disclosure are directed to providing a display apparatus that can block power supplied to a sensing circuit (e.g., a touch sensing circuit) when the sensing circuit does not output a touch driving signal to a touch electrode during a touch sensing period. By blocking power to the sensing circuit when the sensing circuit does not output the touch driving signal to the touch electrode during the touch sensing period, implementations of the present disclosure can therefore provide a display apparatus with reduced power consumption as compared to conventional display apparatuses.

Additional advantages and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description as well as the appended drawings.

It is to be understood that both the foregoing general description and the following detailed description of the present disclosure are example and explanatory and are intended to provide further explanation of the disclosure as claimed.

Advantages and features of the present disclosure, and implementation methods thereof will be clarified through following example implementations described with reference to the accompanying drawings. The present disclosure can, however, be embodied in different forms and should not be construed as limited to the example implementations set forth herein. Rather, these example implementations are provided so that this disclosure is sufficiently thorough and complete to assist those skilled in the art to fully understand the scope of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and may be thus different from those used in actual products.

A shape, a size, a ratio, an angle, and a number disclosed in the drawings for describing implementations of the present disclosure may be provided merely as an example. Thus the present disclosure is not limited to the illustrated details. Like reference numerals refer to like elements throughout. In the following description, when the detailed description of the relevant known function or configuration is determined to unnecessarily obscure the important point of the present disclosure, the detailed description of such known function or configuration will be omitted or may be briefly provided. When “comprise,” “have,” and “include” described in the present disclosure are used, another part can be added unless “only” is used. An element described in a singular form is intended to include a plurality of elements and vice versa, unless the contrary context clearly indicates otherwise.

Any implementation described herein as an “example” is not necessarily to be construed as preferred or advantageous over other implementations.

In construing an element, the element is construed as including an error or tolerance range although there is no explicit description of such an error or tolerance range.

In describing a position relationship, for example, when a position relation between two parts is described as, for example, “on,” “over,” “under,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another and may not define order of sequence. For example, a first element could be termed a second element, and, similarly, a second element could be termed a first element, without departing from the scope of the present disclosure.

In describing elements of the present disclosure, the terms “first,” “second,” “A,” “B,” “(a),” “(b),” etc. can be used. These terms are intended to identify the corresponding elements from the other elements, and basis, order, or number of the corresponding elements should not be limited by these terms. The expression that an element is “connected,” “coupled,” or “adhered” to another element or layer should be understood the element or layer cannot only be directly connected or adhered to another element or layer, but also be indirectly connected or adhered to another element or layer with one or more intervening elements or layers “disposed,” or “interposed” between the elements or layers, unless otherwise specified.

If a component is stated to be “connected,” “coupled,” “adhered,” or “attached” to another component, that component can be connected, coupled, adhered, or attached directly to the other component, but it should be understood that other components can be interposed between the components that can be connected, coupled, adhered, or attached indirectly, without any specific description.

It should be understood that if a component or layer is stated to be “in contact” or “overlapping” with another component or layer, the component or layer can be in direct contact or overlapping with another component or layer, but other components can be interposed between each component that can be indirectly in contact or overlapping without particular explicit description.

The term “at least one” should be understood as including any and all combinations of one or more of the associated listed elements. For example, the meaning of “at least one of a first item, a second item, and a third item” denotes the combination of all items proposed from two or more of the first item, the second item, and the third item as well as the first item, the second item, or the third item. Also, the term “can” used herein includes all meanings and definitions of the word “may”.

“First direction”, “second direction”, “third direction”, “X-axis direction”, “Y-axis direction”, and “Z-axis direction” should not be interpreted only as a geometric relationship perpendicular to each other, but can mean that the configuration of the present disclosure has a wider direction within a range in which the configuration of the present disclosure can functionally act.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Features of various implementations of the present disclosure can be partially or overall coupled to or combined with each other, and can be variously inter-operated with each other and driven technically as those skilled in the art can sufficiently understand.

The implementations of the present disclosure can be carried out independently from each other, or can be carried out together in co-dependent relationship.

Hereinafter, implementations of the present disclosure will be described in detail with reference to the accompanying drawings.

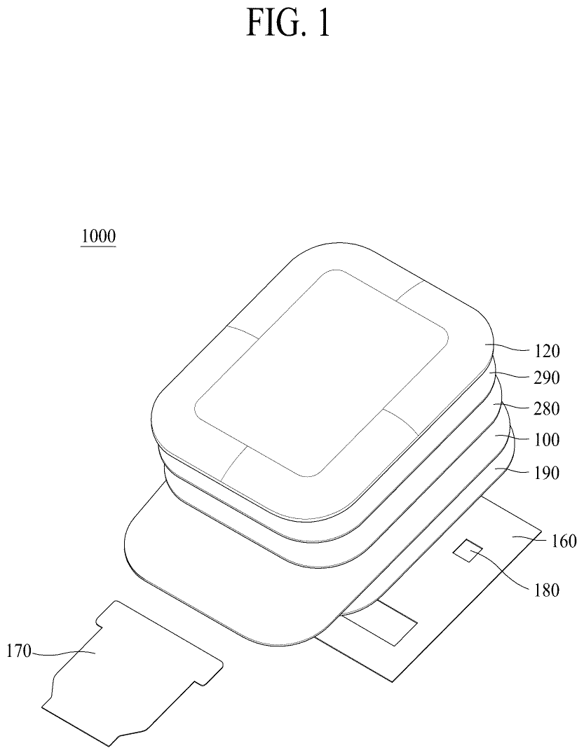

FIG. 1 is a perspective view illustrating a display apparatus according to an implementation of the present disclosure.

Referring to FIG. 1, a display apparatus 1000 according to an implementation of the present disclosure can include a display panel 100, a polarizing layer 280, an adhesive layer 290, a cover member 120, a support substrate 190, a flexible circuit board 170, and a printed circuit board 160.

The display panel 100 can display information and an image to be provided to a user.

The polarizing layer 280 can be disposed on the display panel 100. The polarizing layer 280 can prevent or reduce light generated from an external light source from entering the display panel 100 to affect a light emitting device or the like.

The adhesive layer 290 can attach the cover member 120 to the display panel 100. The adhesive layer 290 can be disposed between the polarizing layer 280 and the cover member 120 to attach the cover member 120 to the polarizing layer 280. The adhesive layer 290 can be one of an optically clear adhesive (OCA), an optically clear resin (OCR), and a pressure sensitive adhesive (PSA).

The cover member 120 can be disposed on the polarizing layer 280. The cover member 120 can be disposed on the adhesive layer 290. The cover member 120 can be a member for protecting the display panel 100. The cover member 120 can be formed of a transparent material.

The support substrate 190 can be disposed between the display panel 100 and the printed circuit board 160. The support substrate 190 can reinforce rigidity of the display panel 100. The support substrate 190 can be a back plate.

The flexible circuit board 170 and the printed circuit board 160 can be disposed on a bottom of the display panel 100. The flexible circuit board 170 and the printed circuit board 160 can be disposed on one edge of the display panel 100. One side of the flexible circuit board 170 can be attached to the display panel 100 and the other side of the flexible circuit board 170 can be attached to the printed circuit board 160. The flexible circuit board 170 can be a flexible film, but implementations of the present disclosure are not limited thereto.

The printed circuit board 160 can include at least one hole 180. An internal component that senses ambient light or temperature can be disposed in an area corresponding to at least one hole 180. For example, the internal component can include at least one of an ambient light sensor (ALS) and a temperature sensor.

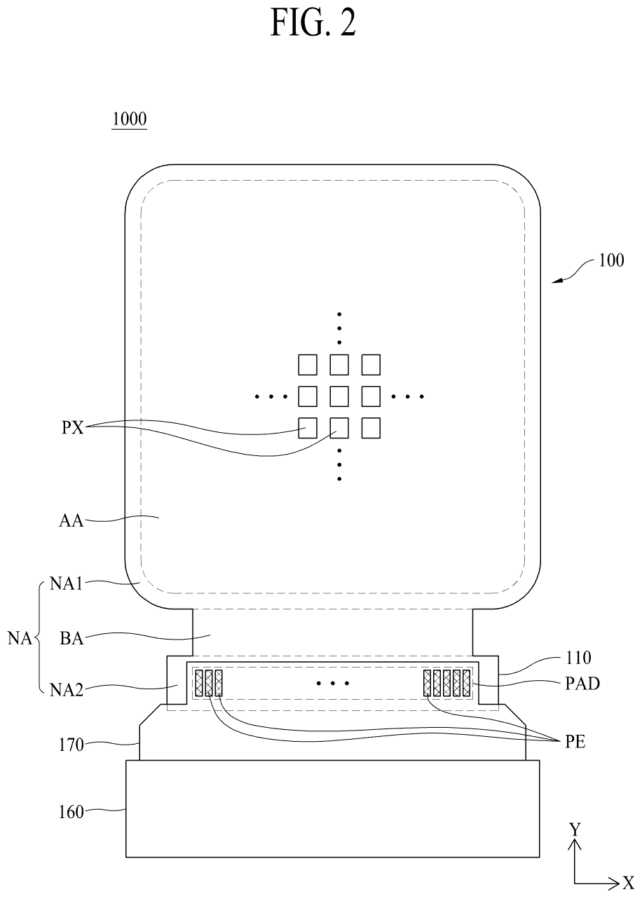

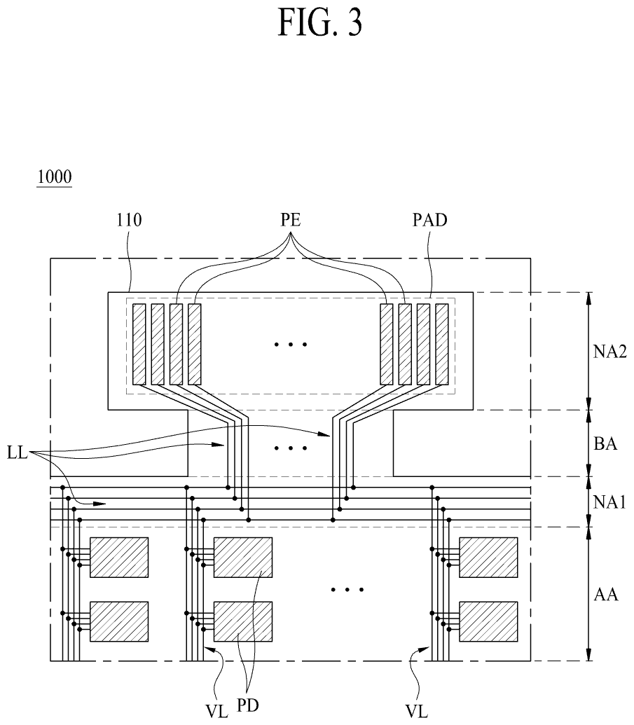

FIG. 2 is a plan view of a display apparatus according to an implementation of the present disclosure and FIG. 3 is an enlarged exemplary diagram of a portion of a display apparatus according to an implementation of the present disclosure.

Referring to FIGS. 2 and 3, the display apparatus 1000 can include the display panel 100, the flexible circuit board 170, and the printed circuit board 160.

The display panel 100 can include a substrate 110. The substrate 110 can be a member that supports other components of the display apparatus 1000. The substrate 110 can be made of an insulating material. For example, the substrate 110 can be made of glass or resin. Also, the substrate 110 can be made of a material having flexibility. For example, the substrate 110 can be made of a plastic material having flexibility, such as polyimide (PI).

For example, the display panel 100 can include a display area AA and a non-display area NA. Therefore, the substrate 110 can include the display area AA and the non-display area NA. The display area AA and the non-display area NA can be applied not only to the description of the substrate 110, but also to the description of the display apparatus 1000.

The display area AA can be an area in which an image is displayed. The display area AA can include a plurality of pixels PX. Each of the plurality of pixels PX can include a plurality of sub-pixels. At least one sub-pixel can be disposed in each of the plurality of sub-pixels.

A type of the light emitting device can be variously changed based on a type of the display apparatus 1000. For example, when the display apparatus 1000 is an inorganic light emitting display apparatus, the light emitting device can be a light-emitting diode (LED), a micro light-emitting diode (Micro-LED), or a mini-light-emitting diode (MLED).

The display area AA can be configured in various shapes according to a design of the display apparatus 1000. For example, the display area AA can be configured in a rectangular shape having four rounded corners. For another example, the display area AA can be configured in a rectangular having four corners, each of which has a right-angle shape, or a circular shape.

Referring to FIG. 3, a plurality of pixel driving circuits PD can be disposed in the display area AA. The plurality of pixel driving circuits PD can be circuits for driving light emitting devices provided in the plurality of sub-pixels.

Each of the plurality of pixel driving circuits PD can include a storage capacitor and a plurality of transistors including a driving transistor. In addition, each of the plurality of pixel driving circuits PD can control a light emitting operation of the plurality of light emitting devices by supplying a control signal, a power source, and a driving current to the light emitting devices provided in the plurality of sub-pixels. For example, the pixel driving circuit PD can include a power line and a signal line for controlling light emission on/off and/or light emission time of the light emitting device. For example, the plurality of pixel driving circuits PD can be manufactured using a metal-oxide-silicon field effect transistor (MOSFET) manufacturing process on a semiconductor substrate.

The non-display area NA can be an area in which no image is displayed. Various lines, circuits, and the like for driving the plurality of pixels PX of the display area AA can be disposed in the non-display area NA. For example, various lines and driving circuits can be mounted in the non-display area NA. Also, a pad part PAD to which an integrated circuit, a printed circuit, and the like is connected can be disposed in the non-display area NA.

For example, the driving circuit can be a data driving circuit and/or a gate driving circuit. Lines to which a control signal for controlling the driving circuits is supplied can be disposed in the non-display area NA. For example, the control signal can include a clock signal, an input data enable signal, and synchronization signals. The control signal can be received through the pad part PAD. For example, link lines LL for transmitting a signal can be disposed in the non-display area NA. For example, a driving component such as the flexible circuit board 170 and the printed circuit board 160 can be connected to the pad part PAD.

According to the present disclosure, the non-display area NA can include a first non-display area NA1, a bending area BA, and a second non-display area NA2. For example, the first non-display area NA1 can be an area surrounding at least a portion of the display area AA. The bending area BA can be an area extending from at least one of a plurality of sides of the first non-display area NA1 and can be a bendable area. The second non-display area NA2 is an area extending from the bending area BA, and the pad part PAD can be disposed in the second non-display area NA2. For example, the bending area BA can be bent, and a remaining area of the substrate 110 except for the bending area BA can be flat. In this case, as the bending area BA is bent, the second non-display area NA2 can be disposed on a rear surface of the display area AA.

A plurality of link lines LL can be disposed in the non-display area NA. The plurality of link lines LL can be lines for transmitting various signals from one or more flexible circuit boards (or flexible films) 170 and the printed circuit board 160 to the display area AA. The plurality of link lines LL can extend from a plurality of pad electrodes PE of the second non-display area NA2 toward the bending area BA and the first non-display area NA1 to be electrically connected to a plurality of driving lines VL of the display area AA.

The plurality of pixel driving circuits PD can be driven by signals transmitted from one or more flexible circuit boards (or flexible films) 170 and the printed circuit board 160 through the driving line VL in the display area AA and the link line LL in the non-display area NA.

For example, each of the driving line VL and the link line LL can be a line for transmitting a signal output from the flexible circuit board (or flexible film) 170 and the printed circuit board 160 to the pixel driving circuit PD. The driving line VL can be disposed in the display area AA to be electrically connected to the pixel driving circuit PD. The driving line VL can extend from the display area AA toward the non-display area NA to be electrically connected to the link line LL. Accordingly, the signal output from the flexible circuit board (or flexible film) 170 and the printed circuit board 160 can be transmitted to the pixel driving circuit PD through the link line LL and the driving line VL.

As the bending area BA is bent, a portion of the link line LL can also be bent with the bending area BA. Stress is concentrated on a portion of the bent link line LL, and thus, a crack can occur in the link line LL. The link line LL can be formed of a conductive material having excellent ductility in order to reduce cracks when the bending area BA is bent. For example, the link line LL can be formed of a conductive material having excellent ductility, such as gold (Au), silver (Ag), aluminum (Al), etc. Also, the link line LL can be formed of one of various conductive materials used in the display area AA. For example, the link line LL can be formed of molybdenum (Mo), chromium (Cr), titanium (Ti), nickel (Ni), neodymium (Nd), copper (Cu), an alloy of silver (Ag) and magnesium (Mg), or an alloy thereof. The link line LL can be formed in a multilayer structure including various conductive materials. For example, the link line LL can be formed in a triple layer structure of titanium (Ti)/aluminum (Al)/titanium (Ti).

The link line LL can be configured in various shapes to reduce stress. At least a portion of the link line LL disposed on the bending area BA can extend in a same direction as the extending direction of the bending area BA, or can extend in a direction different from the extending direction of the bending area BA to reduce stress. For example, when the bending area BA extends in one direction from the first non-display area NA1 to the second non-display area NA2, at least a portion of the link line LL disposed on the bending area BA can extend in a direction inclined to the one direction.

For another example, at least a portion of the link line LL can be formed in various shapes of patterns. For example, at least a portion of the link line LL disposed on the bending area BA can have a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged.

Therefore, in order to reduce or minimize the stress concentrated on the link line LL and the crack due to the stress, the shape of the link line LL can be formed in various shapes including the above-described shape.

According to the present disclosure, a width of the second non-display area NA2 in which the plurality of pad electrodes PE is disposed can be wider than a width of the bending area BA in which only the plurality of link lines LL is disposed. Also, a width of the display area AA in which the plurality of sub-pixels is disposed can be wider than the width of the bending area BA in which only the plurality of link line LL is disposed. A substrate 110 in which a width of the bending area BA is narrower than a width of other areas of the substrate 110 is illustrated in FIGS. 2 and 3. However, a shape of the substrate 110 including the bending area BA is exemplary, and thus, implementations of the present disclosure are not limited thereto.

A pad part PAD including the plurality of pad electrodes PE can be disposed in the second non-display area NA2. A driving component including one or more the flexible circuit boards (or flexible films) 170 and the printed circuit board 160 can be attached to or bonded to the pad part PAD. The plurality of pad electrodes PE are electrically connected to one or more flexible circuit boards (or flexible films), and can transmit various signals (or power) received from the printed circuit board 160 and the flexible circuit board (or flexible film) 170 to the plurality of pixel driving circuits PD in the display area AA.

The flexible circuit board (or flexible film) 170 can be a film having a flexibility and various components can be disposed on the flexible circuit board. For example, a driving IC such as a gate driver IC or a data driver IC can be disposed on the flexible circuit board (or flexible film). In the following description, the driving IC can be referred to as a driving driver.

The driving IC can be a component that processes data and a driving signal for displaying an image. The driving IC can be disposed by a method such as a chip on glass (COG), a chip on film (COF), a tape carrier package (TCP), or the like, but implementations of the present disclosure are not limited thereto. The flexible circuit board (or flexible film) 170 can be attached to or bonded on a plurality of pad electrodes PE through a conductive adhesive layer.

The printed circuit board 160 can be electrically connected to one or more flexible circuit boards (or flexible films) 170, and supply signals to the driving IC. The printed circuit board 160 can be disposed on one side of the flexible circuit board (or flexible film) 170 to be electrically connected to the flexible circuit board (or flexible film). Various components for supplying various signals to the driving IC can be disposed on the printed circuit board 160. For example, various components, such as a timing controller, a power circuit, a memory, a processor, etc., can be disposed on the printed circuit board 160. For example, the printed circuit board 160 can include a power management integrated circuit (PMIC).

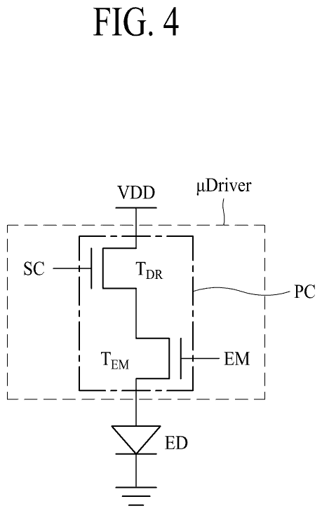

FIG. 4 is an exemplary diagram illustrating a structure of a pixel driving circuit applied to a display apparatus according to an implementation of the present disclosure.

The pixel driving circuit PD described with reference to FIG. 3 can be a micro-driver (μDriver) illustrated in FIG. 4. FIG. 4 illustrates that one light emitting device ED is connected to one micro-driver (μDriver), but is not limited thereto.

For example, eight light emitting devices ED can be connected to one micro-driver (μDriver). For another example, 16 light emitting devices ED can be connected to one micro-driver (μDriver) and 32 light emitting devices ED or 64 light emitting devices ED can be connected to one micro-driver (μDriver). The light emitting device ED can be a micro light emitting device (μLED). In addition, one pixel driving circuit PD (e.g., micro-driver (μDriver)) can be connected to at least two light emitting devices ED. In this case, one pixel driving circuit PD (e.g., micro-driver (μDriver)) can include one or more pixel circuits PC illustrated in FIG. 4. The pixel circuit PC can be connected to at least one light emitting device ED. The pixel circuit PC included in the micro driver μDriver can include a driving transistor TDR and a light emitting transistor TEM.

For example, a high potential power voltage VDD can be applied to a first electrode of the driving transistor TDR, a first electrode of the light emitting transistor TEM can be connected to a second electrode of the driving transistor TDR, and a scan signal SC can be applied to a gate electrode of the driving transistor TDR. The scan signal SC applied to the gate electrode of the driving transistor TDR can be a direct current power source, and a fixed reference voltage can be applied in every frame.

The second electrode of the driving transistor TDR can be connected to a first electrode of the light emitting transistor TEM, the light emitting device ED can be connected to a second electrode of the light emitting transistor TEM, and a light emitting signal EM can be applied to a gate electrode of the light emitting transistor TEM. The light emitting signal EM applied to the gate electrode of the light emitting transistor TEM can be a pulse width modulation (PWM) signal that changes in every frame.

A first electrode of the light emitting device ED can be connected to the second electrode of the light emitting transistor TEM, and a second electrode of the light emitting device ED can be connected to ground. For example, the first electrode of the light emitting device ED can be an anode electrode and the second electrode of the light emitting device ED can be a cathode electrode.

Each of the driving transistor TDR and the light emitting transistor TEM can be an n-type transistor or a p-type transistor.

The driving transistor TDR can be turned on by the scan signal SC applied from a timing controller T-CON and the light emitting transistor TEM can be turned on by the light emitting signal EM. In this case, a driving current can be applied to the light emitting device ED through the driving transistor TDR and the light emitting transistor TEM by the high potential power voltage VDD applied to the first electrode of the driving transistor TDR, and thus the light emitting device ED can emit light.

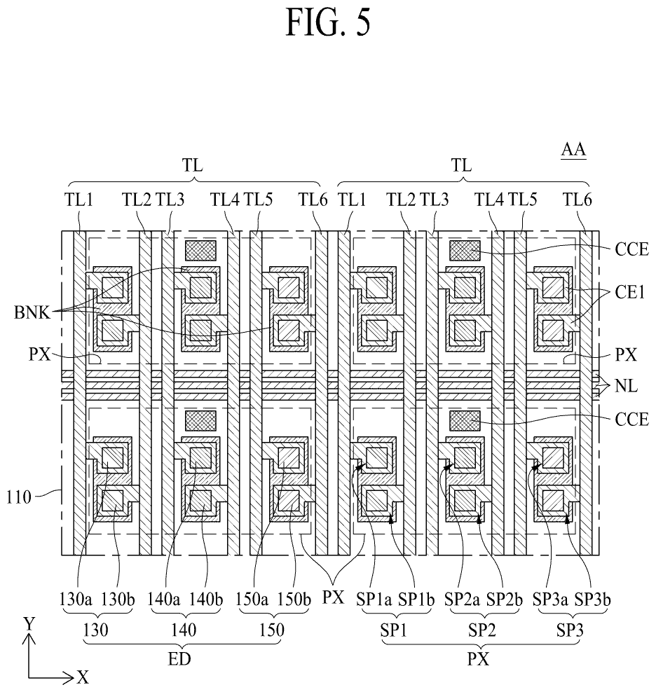

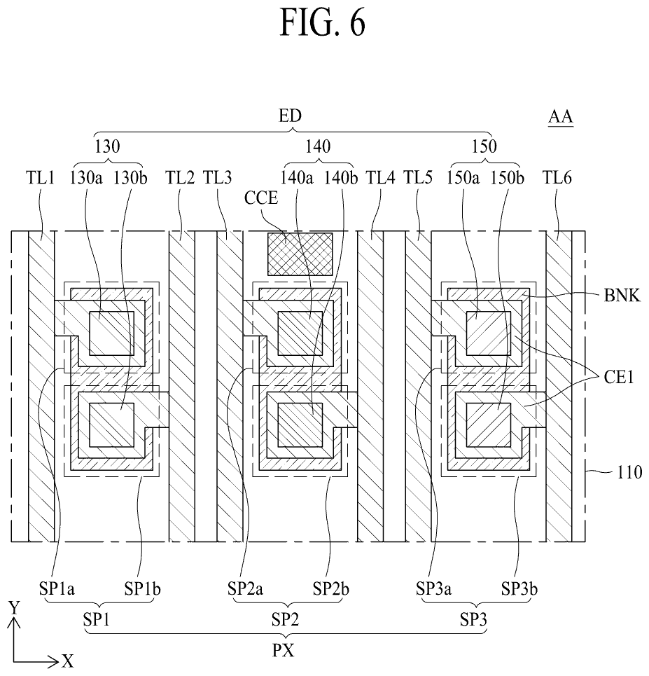

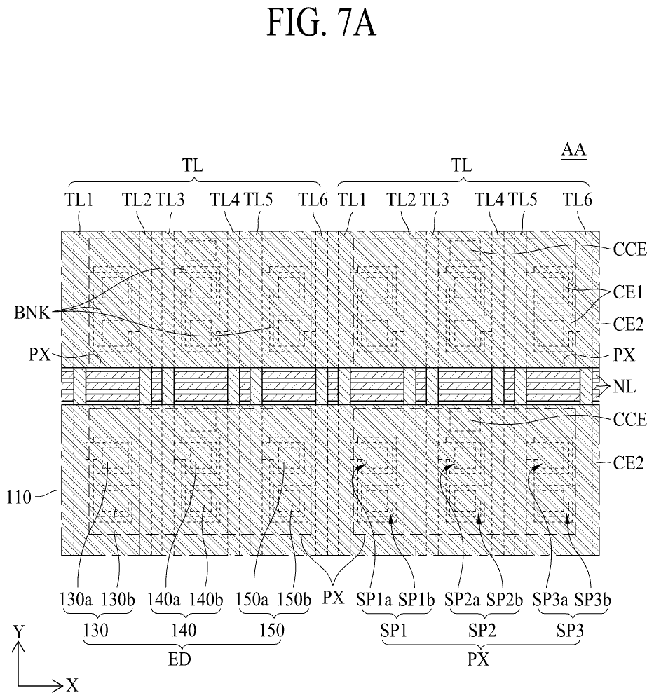

FIGS. 5 to 7B are plan views of a display panel applied to a display apparatus according to an implementation of the present disclosure. For example, FIG. 5 is an enlarged plan view of a portion of the display area AA including a plurality of pixels, FIG. 6 is an enlarged plan view of a part of the display area AA including one pixel, FIG. 7A is another plan view of the area illustrated in FIG. 5, and FIG. 7B is a plan view illustrating two second electrodes CE2 illustrated in FIG. 7A. A plurality of signal lines TL, a plurality of communication lines NL, a plurality of first electrodes CE1, a plurality of banks BNK, and a plurality of light emitting devices ED are illustrated in FIGS. 5 and 6. FIG. 7A illustrates two second electrodes CE2 added to the plan view illustrated in FIG. 5, and FIG. 7B illustrates two second electrodes CE2 illustrated in FIG. 7A.

Referring to FIGS. 5 to 7B, a plurality of pixels PX including a plurality of sub-pixels can be disposed in the display area AA. Each of the plurality of sub-pixels includes a light emitting device ED and can independently output light. The plurality of sub-pixels can be configured in a plurality of rows and a plurality of columns and can be disposed in a matrix form.

The plurality of sub-pixels can include a first sub-pixel SP1, a second sub-pixel SP2, and a third sub-pixel SP3. For example, any one of the first sub-pixel SP1, the second sub-pixel SP2, and the third sub-pixel SP3 can be a red sub-pixel, another can be a green sub-pixel, and the other can be a blue sub-pixel. Types of the plurality of sub-pixels are examples, and implementations of the present disclosure are not limited thereto.

Each of the plurality of pixels PX can include one or more first sub-pixels SP1, one or more second sub-pixels SP2, and one or more third sub-pixels SP3. For example, one pixel PX can include a pair of first sub-pixels SP1, a pair of second sub-pixels SP2, and a pair of third sub-pixels SP3.

The pair of first sub-pixels SP1 can include a 1a-th sub-pixel SP1a and a 1b-th sub-pixel SP1b. The pair of second sub-pixels SP2 can include a 2a-th sub-pixel SP2a and a 2b-th sub-pixel SP2b. The pair of third sub-pixels SP3 can include a 3a-th sub-pixel SP3a and a 3b-th sub-pixel SP3b. For example, one pixel PX can include the 1a-th sub-pixel SP1a, the 1b-th sub-pixel SP1b, the 2a-th sub-pixel SP2a, the 2b-th sub-pixel SP2b, the 3a-th sub-pixel SP3a, and the 3b-th sub-pixel SP3b.

The plurality of sub-pixels constituting one pixel PX can be variously arranged. For example, in one pixel PX, the pair of first sub-pixels SP1 can be disposed in the same column, the pair of second sub-pixels SP2 can be disposed in the same column, and the pair of third sub-pixels SP3 can be disposed in the same column. The first sub-pixel SP1, the second sub-pixel SP2, and the third sub-pixel SP3 can be disposed in the same row. The number and arrangement of the plurality of sub-pixels constituting one pixel PX are examples, and implementations of the present disclosure are not limited thereto.

The plurality of signal lines TL can be disposed in an area between the plurality of sub-pixels. The plurality of signal lines TL can extend in a column direction between the plurality of sub-pixels. The plurality of signal lines TL can be lines that transmit an anode voltage from the pixel driving circuit PD (showed in FIG. 3) to the plurality of sub-pixels. For example, the signal line TL can be electrically connected to the pixel driving circuit PD and the first electrode CE1 of the sub-pixel. The anode voltage output from the pixel driving circuit PD (for example, from the micro-driver (μDriver)) can be transmitted to the first electrode CE1 of the sub-pixel through the signal line TL.

For example, the first electrode CE1 can be an electrode electrically connected to the anode electrode of the light emitting device ED. The anode voltage transmitted through the signal line TL can be transmitted to the anode electrode of the light emitting device ED through the first electrode CE1. That is, the first electrode CE1 is connected to the anode electrode. Accordingly, in the following description, the first electrode CE1 can mean the anode electrode, or can mean a separate electrode connected to the anode electrode.

In the display apparatus according to an example of the present disclosure, instead of forming a plurality of transistors and storage capacitors in each of the plurality of sub-pixels, the pixel driving circuit PD in which the plurality of pixel circuits is integrated is used, and thus, a structure of the display apparatus 1000 can be simplified. In addition, because a circuit disposed in each of the plurality of sub-pixels is integrated in one pixel driving circuit PD, high efficiency and low power driving can be possible.

The plurality of signal lines TL can include a first signal line TL1, a second signal line TL2, a third signal line TL3, a fourth signal line TL4, a fifth signal line TL5, and a sixth signal line TL6. Each of the first signal line TL1 and the second signal line TL2 can be electrically connected to the pair of first sub-pixels SP1. Each of the third signal line TL3 and the fourth signal line TL4 can be electrically connected to the pair of second sub-pixels SP2. Each of the fifth signal line TL5 and the sixth signal line TL6 can be electrically connected to the pair of third sub-pixels SP3.

The first signal line TL1 can be disposed at one side of the pair of first sub-pixels SP1, and the second signal line TL2 can be disposed at the other side of the pair of first sub-pixels SP1. The first signal line TL1 can be electrically connected to one of the pair of first sub-pixels SP1, for example, the first electrode CE1 of the 1a-th sub-pixel SP1a. The second signal line TL2 can be electrically connected to the remaining first sub-pixel SP1 of the pair of first sub-pixels SP1, for example, the first electrode CE1 of the 1b-th sub-pixel SP1b.

The third signal line TL3 can be disposed at one side of the pair of second sub-pixels SP2, and the fourth signal line TL4 can be disposed at the other side of the pair of second sub-pixels SP2. For example, the third signal line TL3 can be disposed adjacent to the second signal line TL2. The third signal line TL3 can be electrically connected to one of the pair of second sub-pixels SP2, for example, the first electrode CE1 of the 2a-th sub-pixel SP2a. The fourth signal line TL4 can be electrically connected to the remaining second sub-pixel SP2 of the pair of second sub-pixels SP2, for example, the first electrode CE1 of the 2b-th sub-pixel SP2b.

The fifth signal line TL5 can be disposed at one side of the pair of third sub-pixels SP3, and the sixth signal line TL6 can be disposed at the other side of the pair of third sub-pixels SP3. For example, the fifth signal line TL5 can be disposed adjacent to the fourth signal line TL4. The sixth signal line TL6 can be disposed adjacent to the first signal line TL1 connected to the adjacent pixel PX. The fifth signal line TL5 can be electrically connected to one of the pair of third sub-pixels SP3, for example, the first electrode CE1 of the 3a-th sub-pixel SP3a. The sixth signal line TL6 can be electrically connected to the remaining third sub-pixel SP3 of the pair of third sub-pixels SP3, for example, the first electrode CE1 of the 3b-th sub-pixel SP3b.

The signal line TL can be formed of a conductive material. For example, the signal line TL can be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc. For another example, the plurality of signal lines TL can be formed of a multilayer structure including conductive materials. For example, the plurality of signal lines TL can be formed of the multilayer structure in which titanium (Ti), aluminum (Al), titanium (Ti), and indium tin oxide (ITO) are stacked.

The plurality of communication lines NL can be disposed in an area between adjacent pixels PX. The communication line NL can be disposed to extend in a row direction in an area between the adjacent pixels PX. The communication line NL can be disposed in an area between adjacent second electrodes CE2 and not overlap the adjacent second electrodes CE2. For example, the communication line NL can be a line used for short-range communication such as near field communication (NFC). The communication line NL can function as an antenna.

According to the present disclosure, a bank BNK can be disposed in each of the plurality of sub-pixels. The bank BNK can be a structure in which the plurality of light emitting devices ED is disposed. The plurality of banks BNK can guide positions of the plurality of light emitting devices ED in a transfer process of the plurality of light emitting devices ED. The plurality of light emitting devices ED can be transferred onto the plurality of banks BNK in the transfer process of the plurality of light emitting devices ED. The entire area of the light emitting device ED can overlap the bank BNK. The plurality of banks BNK can be bank patterns or construction, but implementations of the present disclosure are not limited thereto.

A bank BNK of the first sub-pixel SP1, a bank BNK of the second sub-pixel SP2, and a bank BNK of the third sub-pixel SP3 can be disposed to be spaced apart from each other. The bank BNK of the first sub-pixel SP1, the bank BNK of the second sub-pixel SP2, and the bank BNK of the third sub-pixel SP3 can be configured to be separated. Accordingly, the banks BNK of the first sub-pixel SP1, the second sub-pixel SP2, and the third sub-pixel SP3 to which different types of light emitting devices ED are transferred can be easily identified.

The bank BNK of the 1a-th sub-pixel SP1a and the bank BNK of the 1b-th sub-pixel SP1b can be connected to each other or can be spaced apart from each other. For example, the bank BNK of the 1ast sub-pixel SP1a and the bank BNK of the 1b-th sub-pixel SP1b in which the same light emitting device ED is disposed can be connected or can be separated or spaced apart from each other in consideration of design such as transfer process requirements. Also, the bank BNK of the 2a-th sub-pixel SP2a and the bank BNK of the 2b-th sub-pixel SP2b can be connected to each other or can be separated or spaced apart from each other. The bank BNK of the 3a-th sub-pixel SP3a and the bank BNK of the 3b-th sub-pixel SP3b can be connected to each other or can be separated or spaced apart from each other. Accordingly, the bank BNK of the pair of first sub-pixels SP1, the bank BNK of the pair of second sub-pixels SP2, and the bank BNK of the pair of third sub-pixels SP3 can be variously formed.

For example, each of the plurality of banks BNK can be formed of an organic insulating material. Each of the plurality of banks BNK can be formed of a single layer or a multilayer of an organic insulating material. For example, each of the plurality of banks BNK can be formed of a photo resist, a polyimide (PI), an acryl-based material, or the like.

The first electrode CE1 can be disposed in each of the plurality of sub-pixels. The first electrode CE1 can overlap the bank BNK to be disposed on the bank BNK. The first electrode CE1 can be electrically connected to one of the plurality of signal lines TL.

At least a portion of the first electrode CE1 can extend to an outside of the bank BNK to be electrically connected to the signal line TL closest to the first electrode CE1. A portion of the first electrode CE1 can overlap the bank BNK, with the rest of the first electrode CE1 not overlapping the bank BNK.

For example, a portion of the first electrode CE1 of the 1a-th sub-pixel SP1a can extend to one side area of the 1a-th sub-pixel SP1a to be electrically connected to the first signal line TL1, and a portion of the first electrode CE1 of the 1b-th sub-pixel SP1b can extend to the other side area of the 1b-th sub-pixel SP1b to be electrically connected to the second signal line TL2. A portion of the first electrode CE1 of the 2a-th sub-pixel SP2a can extend to one side area of the 2a-th sub-pixel SP2a to be electrically connected to the third signal line TL3, and a portion of the first electrode CE1 of the 2b-th sub-pixel SP2b can extend to the other side area of the 2b-th sub-pixel SP2b to be electrically connected to the fourth signal line TL4. A portion of the first electrode CE1 of the 3a-th sub-pixel SP3a can extend to one side area of the 3a-th sub-pixel SP3a to be electrically connected to the fifth signal line TL5, and a portion of the first electrode CE1 of the 3b-th sub-pixel SP3b can extend to the other side area of the 3b-th sub-pixel SP3b to be electrically connected to the sixth signal line TL6.

The first electrode CE1 is electrically connected to the anode electrode of the light emitting device ED. The anode voltage from the pixel driving circuit PD can be transmitted to the light emitting device ED via the signal line TL and the first electrode CE1. A different voltage can be applied to the first electrode CE1 of each of the plurality of sub-pixels according to an image that is displayed. For example, different voltage can be applied to the first electrodes CE1 of the plurality of sub-pixels. Accordingly, the first electrode CE1 can be referred to as a pixel electrode.

The first electrode CE1 can be formed of a conductive material. For example, the first electrode CE1 can be formed integrally with the signal line TL. For example, the first electrode CE1 can be formed of the same conductive material as the signal line TL. For example, the first electrode CE1 can be formed of one of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like. For another example, the first electrode CE1 can be formed of a multilayer structure of the conductive material. For example, the plurality of first electrodes CE1 can be formed of the multilayer structure in which titanium (Ti), aluminum (Al), titanium (Ti), and indium tin oxide (ITO) are stacked.

The light emitting device ED can be disposed in each of a plurality of sub-pixels. The plurality of light emitting device ED can be any one of a light-emitting diode (LED) and a micro light-emitting diode (Micro LED). The plurality of light emitting devices ED can overlap the bank BNK and the first electrode CE1 to be disposed on the bank BNK and the first electrode CE1. The entire area of the light emitting device ED can overlap the bank BNK and the first electrode CE1.

The light emitting devices ED can be disposed on the first electrode CE1 and can be electrically connected to the first electrode CE1. Accordingly, the light emitting device ED can output light by using the anode voltage (or the anode current) from the pixel driving circuit PD through the signal line TL and the first electrode CE1.

The plurality of light emitting devices ED can include a first light emitting device 130, a second light emitting device 140, and a third light emitting device 150. The first light emitting device 130 can be disposed in the first sub-pixel SP1. The second light emitting device 140 can be disposed in the second sub-pixel SP2. The third light emitting device 150 can be disposed in the third sub-pixel SP3. For example, one of the first light emitting device 130, the second light emitting device 140, and the third light emitting device 150 can be a red light emitting device, another can be a green light emitting device, and the other can be a blue light emitting device, but implementations of the present disclosure are not limited thereto. Light of various colors including white can be implemented by combining red light, green light, and blue light emitted from the plurality of light emitting devices ED. Types of the plurality of light emitting devices ED are examples, and implementations of the present disclosure are not limited thereto.

The first light emitting device 130 can include a 1a-th light emitting device 130a disposed in the 1a-th sub-pixel SP1a and a 1b-th light emitting device 130b disposed in the 1b-th sub-pixel SP1b. The second light emitting device 140 can include a 2a-th light emitting device 140a disposed in the 2a-th sub-pixel SP2a and a 2b-th light emitting device 140b disposed in the 2b-th sub-pixel SP2b. The third light emitting device 150 can include a 3a-th light emitting device 150a disposed in the 3a-th sub-pixel SP3a and a 3b-th light emitting device 150b disposed in the 3b-th sub-pixel SP3b.

The second electrode CE2 can be disposed in each of the plurality of sub-pixels.

The second electrode CE2 can be disposed on the light emitting device ED. The second electrode CE2 can be electrically connected to the pixel driving circuit PD through contact electrodes CCE.

For example, the second electrode CE2 can be electrically connected to the cathode electrode of the light emitting device ED to transmit the cathode voltage from the pixel driving circuit PD to the light emitting device ED. That is, the second electrode CE2 is connected to the cathode electrode. Therefore, in the following description, the second electrode CE2 can refer to a cathode electrode or a separate electrode connected to the cathode electrode.

The same cathode voltage can be applied to the second electrodes CE2 of the plurality of sub-pixels. For example, the same voltage can be applied to the second electrodes CE2 provided in the plurality of sub-pixels. Accordingly, the second electrode CE2 can be referred to as a common electrode.

At least some of the plurality of sub-pixels can share the second electrode CE2. For example, the second electrode CE2 can be provided in at least two sub-pixels. To provide an additional description, the second electrode CE2 can be provided in at least one pixel PX among a plurality of pixels PX disposed in the same row in the horizontal direction (X-axis direction). For example, one second electrode CE2 can be disposed in a plurality of pixels PX. That is, one second electrode CE2 can be disposed in n sub-pixels (n is a natural number). FIGS. 7A and 7B illustrate a display apparatus in which one second electrode CE2 is provided in two sub-pixel disposed in the horizontal direction (X-axis direction).

In this case, the second electrodes CE2 disposed in the plurality of sub-pixels can be spaced apart from each other or separated from each other. For example, the second electrode CE2 connected to the pixels PX of an n-th row and the second electrode CE2 connected to the pixels PX of an n+1th row can be spaced apart from each other or separated from each other. For example, as illustrated in FIGS. 7a and 7b, the plurality of second electrodes CE2 can be spaced apart from each other with the plurality of communication lines NL extending in a row direction interposed therebetween. Accordingly, the number of the plurality of sub-pixels can be greater than the number of the plurality of second electrodes CE2.

The plurality of second electrodes CE2 can be formed of a transparent conductive material. When the plurality of second electrodes CE2 are formed of the transparent conductive material, light emitted from the light emitting device ED is directed to an upper portion of the second electrode CE2. For example, the second electrode CE2 can be formed of the transparent conductive material such as indium tin oxide (ITO), indium zinc oxide (IZO), indium gallium zinc oxide (IGZO), or the like.

A plurality of contact electrodes CCE can be disposed on the substrate 110. For example, the plurality of contact electrodes CCE can be disposed to be spaced apart from a plurality of banks BNK and a plurality of signal lines TL. Each of the plurality of second electrodes CE2 can overlap at least one contact electrode CCE. For example, one second electrode CE2 can overlap a plurality of contact electrodes CCE.

For example, the plurality of contact electrodes CCE can be electrically connected to the second electrode CE2. The contact electrode CCE can be disposed between the substrate 110 and the second electrode CE2 to transfer the cathode voltage transmitted from the pixel driving circuit PD to the second electrode CE2.

When a micro LED is used as the light emitting device ED, a plurality of micro LEDs can be formed in a wafer and the micro LEDs can be transferred to the substrate 110, and thus the display panel 100 can be manufactured. Various defects can occur in the process of transferring the plurality of light emitting devices ED having a micro size from the wafer to the substrate 110. For example, a non-transmission defect in which the light emitting device ED is not transferred can occur in some sub-pixels, and a defect in which the light emitting device ED is transferred out of a correct position due to an alignment error can occur in some sub-pixels. Also, even if the transfer process has proceeded normally, the transferred light emitting device ED itself can be a defect. Accordingly, the plurality of the same light emitting devices ED can be transferred to one sub-pixel in consideration of the defect during the transfer process of the plurality of light emitting devices ED. After the lighting test of the plurality of light emitting devices ED is performed, only one light emitting device ED finally determined to be normal can be used.

For example, the 1a-th light emitting device 130a and the 1b-th light emitting device 130b can be transferred to one pixel PX, and it is possible to inspect whether there is a defect in the 1a-th light emitting device 130a and the 1b-th light emitting device 130b. If both of the 1a-th light emitting device 130a and the 1b-th light emitting device 130b are determined to be normal, only the 1a-th light emitting device 130b can be used and the 1b-th light emitting device 130b can be not used. As another example, if only the 1b-th light emitting device 130b of the 1a-th light emitting device 130a and the 1b-th light emitting device 130b is determined to be normal, the 1a-th light emitting device 130a is not be used and only the 1b-th light emitting device 130b can be used. Therefore, even if the plurality of the same light emitting devices ED are transferred to one pixel PX, only one light emitting device ED can be finally used.

In this case, any one of the pair of light emitting devices ED can be referred to as a main or primary light emitting device ED, and the other light emitting device ED can be referred to as a redundancy light emitting device ED. The redundancy light emitting device ED can be an extra light emitting device ED transferred to prepare for a defect in the main light emitting device ED. When the main light emitting device ED is defective, the redundancy light emitting device ED can be used instead of the main light emitting device ED. The main light emitting device ED and the redundancy light emitting device ED are transferred to one pixel PX, thereby minimizing deterioration of display quality due to defects in the main light emitting device ED and the redundancy light emitting device ED.

For example, the 1a-th light emitting device 130a, the 2a-th light emitting device 140a, and the 3a-th light emitting device 150a transferred to one pixel PX can be used as the main light emitting device ED, and the 1b-th light emitting device 130b, the 2b-th light emitting device 140b, and the 3b-th light emitting device 150b can be used as the redundancy light emitting device ED.

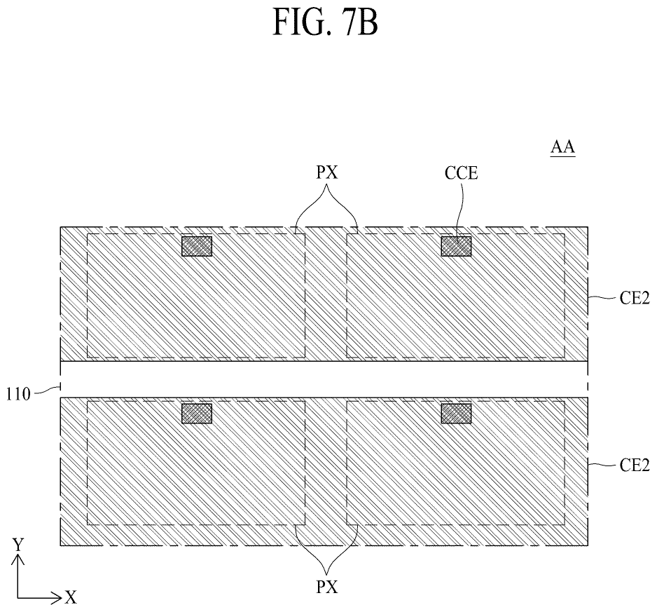

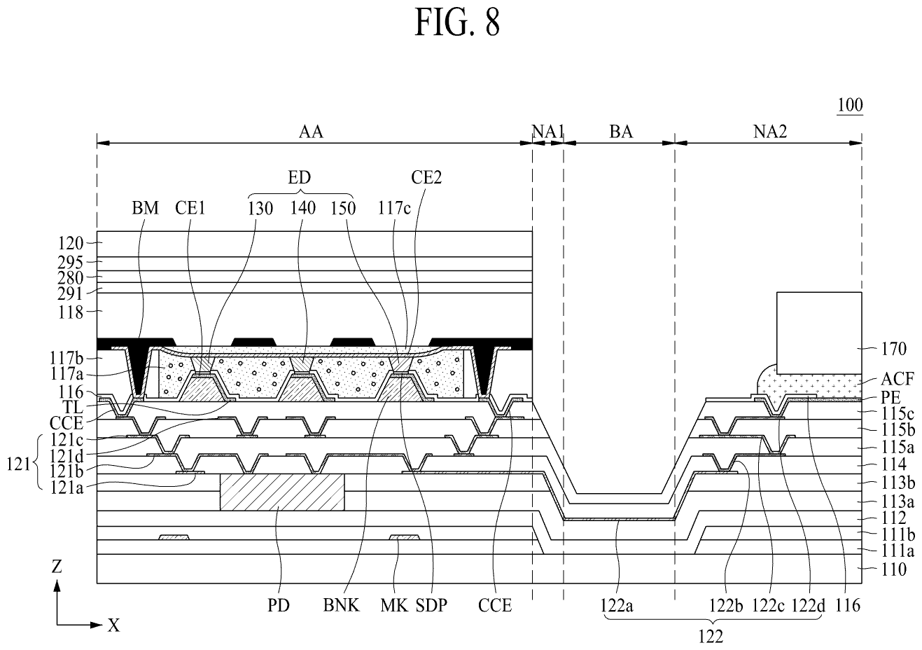

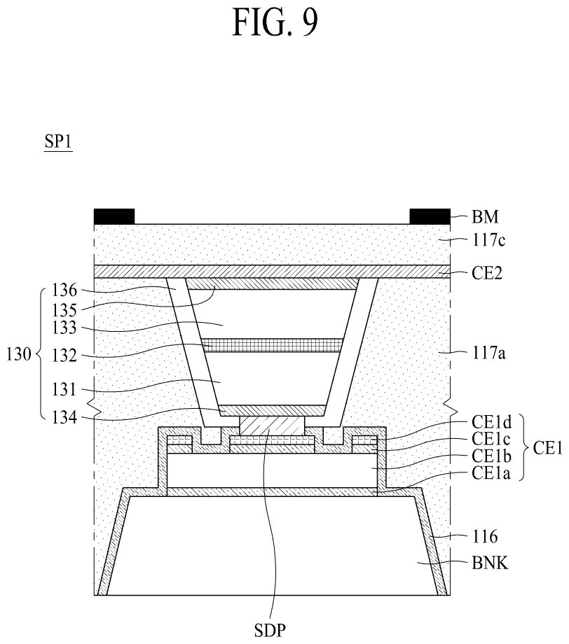

FIG. 8 is an exemplary diagram illustrating a cross-sectional surface of a display panel applied to a display apparatus according to an implementation of the present disclosure, and FIG. 9 is a cross-sectional view of a light emitting device applied to a display apparatus according to an implementation of the present disclosure. For example, FIG. 8 is a cross-sectional view of the display area AA, the first non-display area NA, the bending area BA, and the second non-display area NA2, and FIG. 9 is a cross-sectional view of the light emitting device ED in the display area AA.

Referring to FIG. 8, a first buffer layer 111a and a second buffer layer 111b can be disposed in the remaining area of the substrate 110 except the bending area BA.

The first buffer layer 111a and the second buffer layer 111b can be disposed in the display area AA, the first non-display area NA1, and the second non-display area NA2. The first buffer layer 111a and the second buffer layer 111b can reduce penetration of moisture or impurities through the substrate 110. The first buffer layer 111a and the second buffer layer 111b can be formed of an inorganic insulating material. For example, each of the first buffer layer 111a and the second buffer layer 111b can be formed of a single layer composed of silicon oxide (SiOx) or silicon nitride (SiNx) or a multilayer including at least on of silicon oxide (SiOx) and silicon nitride (SiNx), but implementations of the present disclosure are not limited thereto.

For example, portions of the first buffer layer 111a and the second buffer layer 111b on the bending area BA can be removed. An upper surface of the substrate 110 disposed in the bending area BA cannot be covered by the first buffer layer 111a and the second buffer layer 111b to be exposed. When the first buffer layer 111a and the second buffer layer 111b made of the inorganic insulating material are removed from the bending area BA, cracks, which can occur during bending, in the first buffer layer 111a and the second buffer layer 111b can be reduced or minimized.

A plurality of alignment keys MK can be disposed between the first buffer layer 111a and the second buffer layer 111b. The plurality of alignment keys MK can be formed to identify a position of the pixel driving circuit PD during a manufacturing process of the display panel 100. For example, the plurality of alignment keys MK can align the position of the pixel driving circuit PD transferred onto an adhesive layer 112. However, the plurality of alignment keys MK can be omitted.

An adhesive layer 112 can be disposed on the second buffer layer 111b. The adhesive layer 112 can be disposed in the display area AA, the first non-display area NA1, the bending area BA, and the second non-display area NA2. A portion of the adhesive layer 112 can be removed from the non-display area NA including the bending area BA. For example, the adhesive layer 112 can be formed of any one of an Adhesive polymer, an epoxy resin, a UV curable resin, a polyimide-based resin, an acrylate-based material, a urethane-based material, and a polydimethylsiloxane (PDMS).

In the display area AA, the pixel driving circuit PD can be disposed on the adhesive layer 112. The pixel driving circuit PD can be mounted on the adhesive layer 112 through a transfer process, but implementations of the present disclosure are not limited thereto.

A first protective layer 113a and a second protective layer 113b can be disposed on the adhesive layer 112 and the pixel driving circuit PD. The first protective layer 113a and the second protective layer 113b can surround a side surface of the pixel driving circuit PD. For example, the second protective layer 113b can cover at least a portion of an upper surface of the pixel driving circuit PD. At least one of the first protective layer 113a and the second protective layer 113b disposed on the bending area BA can be omitted. For example, the first protective layer 113a can be entirely disposed in the display area AA and the non-display area NA. Also, the second protective layer 113b can be partially disposed in the display area AA, the first non-display area NA1, and the second non-display area NA2. Moreover, in some implementations, the second protective layer 113b is not disposed in the bending area BA.

The first protective layer 113a and the second protective layer 113b can be formed of an organic insulating material. For example, the first protective layer 113a and the second protective layer 113b can be formed of a photo resist, polyimide (PI), a photo acryl-based material, or the like. The first protective layer 113a and the second protective layer 113b can be an overcoating layer or an insulating layer.

According to the present disclosure, a plurality of first connection lines 121 can be disposed on the second protective layer 113b in the display area AA. The first connection line 121 can be a line for electrically connecting the pixel driving circuit PD to other devices. The pixel driving circuit PD can be electrically connected to the signal line TL, the contact electrode CCE or the like through the first connection line 121.

The first connection line 121 can include a 1a-th connection line 121a, a 1b-th connection line 121b, a 1c-th connection line 121c, and a 1d-th connection line 121d.

The plurality of 1a-th connection lines 121a can be disposed on the second protective layer 113b. The plurality of 1a-th connection lines 121a can be electrically connected to the pixel driving circuit PD. The 1a-th connection lines 121a can transmit voltages output from the pixel driving circuit PD to the first electrode CE1 or the second electrode CE2.

A third protective layer 114 can be disposed on the second protective layer 113b. The third protective layer 114 can be disposed on the entire display area AA and the non-display area NA. In the bending area BA, the third protective layer 114 can disposed on or cover a side surface of the second protective layer 113b and an upper surface of the first protective layer 113a. The third protective layer 114 can be formed of an organic insulating material. The third protective layer 114 can be formed of a photo resist, polyimide (PI), a photo acryl-based material, or the like. For example, the first protective layer 113a, the second protective layer 113b, and the third protective layer 114 can be formed of the same material, but implementations of the present disclosure are not limited thereto.

The plurality of 1b-th connection lines 121b can be disposed on the third protective layer 114. The 1b-th connection lines 121b can be connected to the pixel driving circuit PD through the 1a-th connection lines 121a or can be directly connected to the pixel driving circuit PD. For example, a portion of the 1b-th connection line 121b can be directly connected to the pixel driving circuit PD through a contact hole of the third protective layer 114. The other portion of the 1b-th connection line 121b can be electrically connected to the 1a-th connection line 121a through a contact hole of the third protective layer 114. However, implementations of the present disclosure are not limited thereto. For example, the voltage output from the pixel driving circuit PD can be transmitted to the first electrode CE1 or the second electrode CE2 through a connection line different from the 1b-th connection lines 121b.

A first insulating layer 115a can be disposed on the plurality of 1b-th connection lines 121b. The first insulating layer 115a can be disposed in the entire display area AA and the non-display area NA, but implementations of the present disclosure are not limited thereto. The first insulating layer 115a can be formed of an organic insulating material. The first insulating layer 115a can be formed of a photo resist, polyimide (PI), a photo acryl-based material, or the like.

The plurality of 1c-th connection lines 121c can be disposed on the first insulating layer 115a. The 1c-th connection lines 121c can be electrically connected to the 1b-th connection lines 121b. For example, the 1c-th connection lines 121c can be electrically connected to the 1b-th connection lines 121b through a contact hole of the first insulating layer 115a.

A second insulating layer 115b can be disposed on the plurality of 1c-th connection lines 121c. The second insulating layer 115b can be disposed in the remaining area except for the bending area BA. The second insulating layer 115b can be disposed in the display area AA, the first non-display area NA1, and the second non-display area NA2. For example, at least a portion of the second insulating layer 115b disposed in the bending area BA can be removed. The second insulating layer 115b can be formed of an organic insulating material, but implementations of the present disclosure are not limited thereto. For example, the second insulating layer 115b can be formed of a photo resist, polyimide (PI), a photo acryl-based material, or the like.

The plurality of 1d-th connection lines 121d can be disposed on the second insulating layer 115b. The 1d-th connection lines 121d can be electrically connected to the 1c-th connection lines 121c. For example, the 1d-th connection lines 121d can be electrically connected to the 1c-th connection lines 121c through a contact hole of the second insulating layer 115b.

The 1d-th connection line 121d can be connected to the contact electrode CCE through a contact hole of a third insulating layer 115c, and thus, the contact electrode CCE and the pixel driving circuit PD can be electrically connected to the first connection line 121.

That is, the contact electrode CCE connected to the second electrode CE2 can be electrically connected to the pixel driving circuit PD through the 1d-th connection line 121d, the 1c-th connection line 121c, the 1b-th connection line 121b, and the 1a-th connection line 121a.

However, the 1d-th connection line 121d can be directly connected to the signal line TL through a contact hole disposed in the third insulating layer 115c, or can be electrically connected to the signal ling TL through other additional line or electrode, and thus, the signal line TL and the pixel driving circuit PD can be electrically connected to each other by the first connection line 121.

The signal line TL can be formed of at least one of the 1a-th to 1d-th connection lines 121a to 121d, or can be connected to the first connection line 121.

A plurality of second connection lines 122 can be disposed on the second protective layer 113b in the non-display area NA. The second connection lines 122 can be a line for transmitting a signal received from the flexible circuit board (or a flexible film) 170 and a printed circuit board 160 to the pixel driving circuit PD of the display area AA.

For example, the plurality of second connection lines 122 can be electrically connected to the plurality of pad electrodes PE to receive signals from flexible circuit boards (or flexible films) 170 and printed circuit boards 160.

For example, the plurality of second connection lines 122 can extend from the pad part PAD toward the display area AA to transmit signals to the lines of the display area AA. In this case, each of the plurality of second connection lines 122 can function as link lines LL (showed in FIG. 3). The second connection line 122 can include a 2a-th connection line 122a, a 2b-th connection line 122b, a 2c-th connection line 122c, and a 2d-th connection line 122d.

The plurality of 2a-th connection lines 122a can be disposed on the second protective layer 113b. The plurality of 2a-th connection lines 122a can extend from the second non-display area NA2 to the bending area BA and the first non-display area NA1. The plurality of 2a-th connection lines 122a can transmit signals received from the flexible circuit board (or flexible film 170 and the printed circuit board 160 to the pixel driving circuit PD of the display area AA. Accordingly, the 2a-th connection line 122a can be electrically connected to the pad electrode PE and the pixel driving circuit PD, respectively. For example, the 2a-th connection line 122a can extend to the display area AA to be directly connected to the pixel driving circuit PD in the display area AA, or can be electrically connected to the pixel driving circuit PD through other additional line or electrodes. Also, the 2a-th connection line 122a can be electrically connected to the pad electrode PE in the second non-display area NA2 through the 2b-th connection line 122b, the 2c-th connection line 122c, and the 2d-th connection line 122d. Therefore, the pixel driving circuit PD and the pad electrode PE can be electrically connected by the second connection line 122.

The plurality of 2b-th connection lines 122b can be disposed on the third protective layer 114. 2b-th connection lines 122b can be disposed in the second non-display area NA2. The 2b-th connection lines 122b can be electrically connected to the 2a-th connection lines 122a through a contact hole of the third protective layer 114. Therefore, signals from the flexible circuit board (or flexible film) 170 and the printed circuit board 160 can be transmitted to the 2a-th connection lines 122a through the 2b-th connection lines 122b.

The 2c-th connection line 122c can be disposed on the first insulating layer 115a. The 2c-th connection line 122c can be disposed in the second non-display area NA2. The 2c-th connection line 122c can be electrically connected to the 2b-th connection line 122b through a contact hole of the first insulating layer 115a. Accordingly, signals from the flexible circuit board (or flexible film) 170 and the printed circuit board 160 can be transmitted to the 2a-th connection line 122a through the 2c-th connection line 122c and the 2b-th connection line 122b.

The 2d-th connection line 122d can be disposed on the second insulating layer 115b. The 2d-th connection line 122d can be disposed in the second non-display area NA2. The 2d-th connection line 122d can be electrically connected to the 2c-th connection line 122c through a contact hole of the second insulating layer 115b.

Accordingly, signals from the flexible circuit board (or flexible film) 170 and the printed circuit board 160 can be transmitted to the 2a-th connection line 122a through the 2d-th connection line 122d, the 2c-th connection line 122c, and the 2b-th connection line 122b.

In addition, the 2a-th connection line 122a can extend to the display area AA through the bending area BA, and can be electrically connected to the pixel driving circuit PD in the display area AA.

Accordingly, the pad electrode PE provided in the second non-display area NA2 can be electrically connected to the pixel driving circuit PD provided in the display area AA through the 2d-th connection line 122d, the 2c-th connection line 122c, the 2b-th connection line 122b, and the 2a-th connection line 122a in the bending area BA.

Each of the first connection line 121 and the second connection line 122 can be formed of a conductive material having excellent ductility or various conductive materials used in the display area AA. For example, the second connection line 122 partially disposed in the bending area BA can be formed of a conductive material having excellent ductility, such as gold (Au), silver (Ag), or aluminum (Al). For another example, each of the first connection lines 121 and the second connection lines 122 can be formed of molybdenum (Mo), chromium (Cr), titanium (Ti), nickel (Ni), neodymium (Nd), copper (Cu), an alloy of silver (Ag) and magnesium (Mg), or an alloy thereof, but implementations of the present disclosure are not limited thereto.

A third insulating layer 115c can be disposed on the plurality of first connection lines 121 and the plurality of second connection lines 122. The third insulating layer 115c can be disposed in the remaining area except for the bending area BA. The third insulating layer 115c can be disposed in the display area AA, the first non-display area NA1, and the second non-display area NA2. At least a portion of the third insulating layer 115c in the bending area BA can be removed. The third insulating layer 115c can be formed of an organic insulating material, but implementations of the present disclosure are not limited thereto. For example, the third insulating layer 115c can be formed of a photo resist, polyimide (PI), a photo acryl-based material, or the like.

A bank BNK can be disposed on the third insulating layer 115c in the display area AA. The bank BNK can overlap the sub-pixel. In some implementations, the bank BNK is not disposed in the first non-display area NA1, the second non-display area NA2, and the bending area BA. One or more light emitting devices ED of the same type can be disposed on an upper portion of the bank BNK.

In the display area AA, a plurality of signal lines TLs can be disposed on the third insulating layer 115c. The signal line TL can be disposed between the plurality of banks BNK. For example, the signal line TL can be disposed adjacent to any one of the plurality of banks BNK. The signal line TL can be electrically connected to the first connection line 121, for example, the 1d-th connection line 121d.

A plurality of contact electrodes CCE can be disposed on the third insulating layer 115c in the display area AA. The contact electrode CCE can supply the cathode voltage transmitted from the pixel driving circuit PD to the second electrode CE2. The contact electrode CCE can be electrically connected to the first connection line 121, for example, the 1d-th connection line 121d.

A first electrode CE1 can be disposed on the bank BNK. For example, the first electrode CE1 can extend from the adjacent signal line TL to an upper portion of the bank BNK. The first electrode CE1 can be disposed on an upper surface of the bank BNK and a side surface of the bank BNK. For example, the first electrode CE1 can extend from the signal line TL on an upper surface of the third insulating layer 115c to the side surface of the bank BNK and the upper surface of the bank BNK. The first electrode CE1 can be integrally formed with the signal line TL.

Referring to FIG. 9, the first electrode CE1 can include a plurality of conductive layers. For example, the first electrode CE1 can include a first conductive layer CE1a, a second conductive layer CE1b, a third conductive layer CE1c, and a fourth conductive layer CE1d.

The first conductive layer CE1a can be disposed on the bank BNK. The second conductive layer CE1b can be disposed on the first conductive layer CE1a. The third conductive layer CE1c can be disposed on the second conductive layer CE1b, and the fourth conductive layer CE1d can be disposed on the third conductive layer CE1c. For example, the first conductive layer CE1a, the second conductive layer CE1b, the third conductive layer CE1c, and the fourth conductive layer CE1d can be formed of titanium (Ti), molybdenum (Mo), aluminum (Al), or titanium (Ti) and indium tin oxide (ITO), but implementations of the present disclosure are not limited thereto.

Some of the plurality of conductive layers included in the first electrode CE1 having high reflection efficiency can be used as an alignment key and/or a reflector for aligning the light emitting device ED. For example, the second conductive layer CE1b among the plurality of conductive layers of the first electrode CE1 can include a reflective material. For example, the second conductive layer CE1b can include aluminum (Al). In this case, the second conductive layer CE1b can be used as a reflective plate. Also, due to a high reflection efficiency of the second conductive layer CE1b, identification can be easily performed in a manufacturing process, and thus an arrangement position or a transfer position of the light emitting device ED can be arranged with respect to the second conductive layer CE1b.

For example, in order to use the second conductive layer CE1b as the reflective plate, the third conductive layer CE1c and the fourth conductive layer CE1d covering the second conductive layer CE1b can be partially removed or etched. Portions of the third and fourth conductive layers CE1c and CE1d disposed on the bank BNK can be removed or etched to expose an upper surface of the second conductive layer CE1b. A central portion and an edge portion of the third and fourth conductive layers CE1c and CE1d on which a solder pattern SDP is disposed can remain, and remaining portions except for the center portion and the edge portion of the third and fourth conductive layers CE1c and CE1d can be removed. In some implementations, the central portion and the edge portion of each of the third conductive layer CE1c made of titanium (Ti) and the fourth conductive layer CE1d made of indium tin oxide (ITO) is not etched. Thus, another conductive layer of the first electrode CE1 can be prevented from being corroded by a TMAH (Tetra Methyl Ammonium Hydroxide) solution used in a mask process of the first electrode CE1.

The first conductive layer CE1a and the third conductive layer CE1c can include titanium (Ti) or molybdenum (Mo). The second conductive layer CE1b can include aluminum (Al). The fourth conductive layer CE1d can include a transparent conductive oxide layer, such as indium tin oxide (ITO) or indium zinc oxide (IZO), which has high adhesion to the solder pattern SDP and has corrosion resistance and acid resistance.

The first conductive layer CE1a, the second conductive layer CE1b, the third conductive layer CE1c, and the fourth conductive layer CE1d can be sequentially deposited and then patterned by a photolithography process and an etching process.

Each of the signal line TL, the contact electrode CCE, and the pad electrode PE disposed on the same layer as the first electrode CE1 can be formed of multiple layers of conductive materials, but implementations of the present disclosure are not limited thereto. For example, each of the signal line TL, the contact electrode CCE, and the pad electrode PE can be formed of multiple layers in which indium tin oxide (ITO), titanium (Ti), aluminum (Al), and titanium (Ti) are stacked.

A solder pattern SDP can be disposed on the first electrode CE1 in each of the plurality of sub-pixels. The solder pattern SDP can bond the light emitting device ED to the first electrode CE1. The first electrode CE1 and the light emitting device ED can be electrically connected to each other through eutectic bonding using the solder pattern SDP, but implementations of the present disclosure are not limited thereto. For example, when the solder pattern SDP is formed of indium (In), and the anode electrode 134 of the light emitting device ED is formed of gold (Au), the solder pattern SDP and the anode electrode 134 can be bonded to each other by applying heat and pressure in the transfer process of the light emitting device ED. The light emitting device ED can be bonded to the solder pattern SDP and the first electrode CE1 without a separate adhesive member through eutectic bonding. The solder pattern SDP can be formed of indium (In), tin (Sn), or alloys thereof. For example, the solder pattern SDP can be a bonding pad or the like.

A passivation layer 116 can be disposed on the plurality of signal lines TL, the plurality of first electrodes CE1, the plurality of contact electrodes CCE, and the third insulating layer 115c. For example, the passivation layer 116 can be disposed in the display area AA, the first non-display area NA1, and the second non-display area NA2. A portion of the passivation layer 116 disposed in the bending area BA can be removed. A portion of the passivation layer 116 covering the plurality of pad electrodes PE can be removed in the second non-display area NA2. A portion of the passivation layer 116 covering the plurality of contact electrodes CCE can be removed in the display area AA. The passivation layer 116 covering the solder pattern SDP can be removed in the display area AA. The passivation layer 116 can cover the first electrode CE1. The passivation layer 116 can cover a portion of the exposed upper surface of a second conductive layer CE1b.

Because the passivation layer 116 covers the remaining areas while exposing a portion of the plurality of pad electrodes PE, a portion of the plurality of contact electrodes CCE, and a portion of the solder pattern SDP, penetration of moisture or impurities flowing into the light emitting device ED can be reduced. The passivation layer 116 can be formed of a single layer or multiple layers including silicon oxide (SiOx) or silicon nitride (SiNx). For example, the passivation layer 116 can be a protective layer or an insulating layer. The passivation layer 116 can include a hole exposing the solder pattern SDP and holes exposing the contact electrode CCE.

In each of the plurality of sub-pixels, the light emitting device ED can be disposed on the solder pattern SDP. The first light emitting device 130 can be disposed in the first sub-pixel SP1. The second light emitting device 140 can be disposed in the second sub-pixel SP2. The third light emitting device 150 can be disposed in the third sub-pixel SP3.

The light emitting device ED can be formed on silicon wafers by means of metal organic vapor deposition (MOCVD), chemical vapor deposition (CVD), plasma-enhanced chemical vapor deposition (PECVD), molecular beam growth (MBE), hydride vapor deposition (HVPE), or sputtering, but implementations of the present disclosure are not limited thereto.

The first light emitting device 130 can include an anode electrode 134, a first semiconductor layer 131, an active layer 132, a second semiconductor layer 133, a cathode electrode 135, and an encapsulation layer 136. For example, the encapsulation layer 136 can be excluded in the first light emitting device 130.

The first semiconductor layer 131 can be disposed on the solder pattern SDP. The second semiconductor layer 133 can be disposed on the first semiconductor layer 131.

For example, each of the first semiconductor layer 131 and the second semiconductor layer 133 can formed of a compound semiconductor such as a group III-V or a group II-VI, and can be doped with impurities (or dopants). For example, one of the first semiconductor layer 131 and the second semiconductor layer 133 can be a semiconductor layer doped with n-type impurities, and the other can be a semiconductor layer doped with p-type impurities. For example, each of the first semiconductor layer 131 and the second semiconductor layer 133 can be a layer in which an n-type or p-type impurity is doped into a material such as gallium nitride (GaN), gallium phosphide (GaP), gallium arsenic phosphide (GaAsP), aluminum gallium indium phosphide (AlGaInP), indium aluminum phosphide (InAlP), aluminum gallium nitride (AlGaN), aluminum indium nitride (AlInN), aluminum gallium nitride (AlInGaN), aluminum gallium arsenic (AlGaAs), gallium arsenic (AlGaAs), or a material such as gallium arsenic (GaAs). The n-type impurity can be silicon (Si), germanium (Ge), selenium (Se), carbon (C), tellurium (Te), tin (Sn), or the like. The p-type impurity can be magnesium (Mg), zinc (Zn), calcium (Ca), strontium (Sr), barium (Ba), beryllium (Be), or the like,

Each of the first semiconductor layer 131 and the second semiconductor layer 133 can be a nitride semiconductor including the n-type impurity or a nitride semiconductor including the p-type impurity. For example, the first semiconductor layer 131 can be a nitride semiconductor including the p-type impurity, and the second semiconductor layer 133 can be a nitride semiconductor including the n-type impurity.

The active layer 132 can be disposed between the first semiconductor layer 131 and the second semiconductor layer 133. The active layer 132 can emit light by receiving holes and electrons from the first semiconductor layer 131 and the second semiconductor layer 133. For example, the active layer 132 can be formed of one of a single well structure, a multi-well structure, a single quantum well structure, a multi-quantum well (MQW) structure, a quantum dot structure, and a quantum line structure. The active layer 132 can be formed of indium gallium nitride (InGaN), gallium nitride (GaN), or the like.

For another example, the active layer 132 can include a multi-quantum well (MQW) structure having a well layer and a barrier layer having a band gap higher than that of the well layer. For example, the active layer 132 can include InGaN as a well layer, and can include an AlGaN layer as a barrier layer.

The anode electrode 134 can be disposed between the first semiconductor layer 131 and the solder pattern SDP. The anode electrode 134 can electrically connect the first semiconductor layer 131 to the first electrode CE1. The anode voltage output from the pixel driving circuit PD can be applied to the first semiconductor layer 131 through the signal line TL, the first electrode CE1, and the anode electrode 134. The anode electrode 134 can be formed of a conductive material capable of eutectic bonding with the solder pattern SDP. For example, the anode electrode 134 can be formed of gold (Au), tin (Sn), tungsten (W), silicon (Si), silver (Ag), titanium (Ti), iridium (Ir), chromium (Cr), indium (In), zinc (Zn), lead (Pb), platinum (Pt), copper (Cu), or alloys thereof.

The cathode electrode 135 can be disposed on the second semiconductor layer 133. For example, the cathode electrode 135 can electrically connect the second semiconductor layer 133 to the second electrode CE2. The cathode voltage output from the pixel driving circuit PD can be applied to the second semiconductor layer 133 through the contact electrode CCE, the second electrode CE2, and the cathode electrode 135. The cathode electrode 135 can be formed of a transparent conductive material to allow light emitted from the light emitting device ED to be directed to an upper portion of the light emitting device ED. For example, the cathode electrode 135 can be formed of a material such as indium tin oxide (ITO), indium zinc oxide (IZO), indium gallium zinc oxide (IGZO), or the like.

The encapsulation layer 136 can be disposed on at least a portion of each of the first semiconductor layer 131, the active layer 132, the second semiconductor layer 133, the anode electrode 134, and the cathode electrode 135. For example, the encapsulation layer 136 can surround at least a portion of each of the first semiconductor layer 131, the active layer 132, the second semiconductor layer 133, the anode electrode 134, and the cathode electrode 135.

The encapsulation layer 136 can protect the first semiconductor layer 131, the active layer 132, and the second semiconductor layer 133. The encapsulation layer 136 can be disposed on a side surface of the first semiconductor layer 131, a side surface of the active layer 132, and a side surface of the second semiconductor layer 133.

The encapsulation layer 136 can be disposed on at least a portion of the anode electrode 134 and the cathode electrode 135. For example, the encapsulation layer 136 can be disposed on the edge portion (or one side) of the anode electrode 134 and the edge portion (or one side) of the cathode electrode 135. At least a portion of the anode electrode 134 can be exposed by the encapsulation layer 136, and thus the anode electrode 134 can connect with the solder pattern SDP. For example, at least a portion of the cathode electrode 135 can be exposed by the encapsulation layer 136, and thus the cathode electrode 135 can connect with the second electrode CE2. The encapsulation layer 136 can be formed of an insulating material such as silicon nitride (SiNx) or silicon oxide (SiOx).

For another example, the encapsulation layer 136 can be a layer in which a reflective material is distributed in a resin layer. The encapsulation layer 136 can be manufactured as a reflector having various structures. Light emitted from the active layer 132 can be reflected upward by the encapsulation layer 136 so that light extraction efficiency can be improved. In this case, the encapsulation layer 136 can be a reflective layer.

The light emitting device ED has been described as a vertical structure, but implementations of the present disclosure are not limited thereto. For example, the light emitting device ED can have a lateral structure or a flip chip structure.

Although the first light emitting device 130 has been described above with reference to FIG. 9, the second light emitting device 140 and the third light emitting device 150 can have substantially the same structure as the first light emitting device 130. For example, each of the second light emitting device 140 and the third light emitting device 150 can have substantially the same configuration as the first semiconductor layer 131, the active layer 132, the second semiconductor layer 133, the anode electrode 134, the cathode electrode 135, and the encapsulation layer 136.

According to the present disclosure, as illustrated in FIGS. 8 and 9, a first optical layer 117a surrounding the plurality of light emitting devices ED can be disposed in the display area AA. For example, the first optical layer 117a can cover the side surfaces of the light emitting devices ED and the side surfaces of the plurality of banks BNK. The first optical layer 117a can cover a portion of the passivation layer 116. The first optical layer 117a can be disposed between the second electrode CE2, the passivation layer 116, and the plurality of light emitting devices.

The first optical layer 117a can be disposed between the plurality of light emitting devices ED included in one pixel PX and cover the plurality of light emitting devices ED included in one pixel PX. Also, the first optical layer 117a can be disposed between the plurality of banks BNK included in one pixel PX and cover the plurality of light emitting devices ED included in one pixel PX. For example, the first optical layer 117a can extend in the first direction, and the plurality of first optical layers 117a can be spaced apart from each other in the second direction in a plan view. For example, the first optical layer 117a can be disposed between the passivation layer 116 and the second electrode CE2 to surround the side surface of the light emitting device ED and the side surface of the bank BNK. The first optical layer 117a can be referred to as a diffusion layer, a sidewall diffusion layer, or the like. In the following description, the first direction can be the X-axis direction illustrated in FIG. 5, and the second direction can be the Y-axis direction illustrated in FIG. 5. For example, the first direction and the second direction are different directions. Accordingly, in the following description, reference numeral X can be assigned to the first direction and reference numeral Y can be assigned to the second direction.

The first optical layer 117a can include an organic insulating material in which fine particles are distributed. For example, the first optical layer 117a can be formed of siloxane in which fine metal particles such as titanium dioxide (TiO2) particles are distributed. Light from the plurality of light emitting devices ED can be scattered by fine particles distributed in the first optical layer 117a and emitted to an outside of the display panel 100. Accordingly, the first optical layer 117a can improve extraction efficiency of light emitted from the plurality of light emitting devices ED.

The first optical layer 117a can be disposed in each of the plurality of pixels PX or can be disposed in some pixels PX disposed in the same row. For example, the first optical layer 117a can be disposed in each of the plurality of pixels PX. Also, the plurality of pixels PX can share one first optical layer 117a. For another example, each of the plurality of sub-pixels can separately include a first optical layer 117a.

The second optical layer 117b can be disposed on the passivation layer 116 in the display area AA. For example, the second optical layer 117b can surround the first optical layer 117a. For example, the second optical layer 117b can be in contact with a side surface of the first optical layer 117a. For example, the second optical layer 117b can be disposed in an area between the plurality of pixels PX. However, implementations of the present disclosure are not limited thereto. The second optical layer 117b can be referred to as a diffusion layer, a window diffusion layer, or the like.

The second optical layer 117b can be formed of an organic insulating material, but implementations of the present disclosure are not limited thereto. The second optical layer 117b can be formed of the same material as the first optical layer 117a, but implementations of the present disclosure are not limited thereto. For example, the first optical layer 117a can include fine particles, and the second optical layer 117b can exclude fine particles. For example, the second optical layer 117b can be formed of siloxane.

A thickness of the first optical layer 117a can be less than a thickness of the second optical layer 117b. Accordingly, in a plan view, an area in which the first optical layer 117a is disposed can include a concave portion recessed from an upper surface of the second optical layer 117b.

The second electrode CE2 can be disposed on the first optical layer 117a and the second optical layer 117b. The second electrode CE2 can be electrically connected to the plurality of contact electrodes CCE through a contact hole in the second optical layer 117b. The second electrode CE2 can be disposed on a plurality of light emitting devices ED. The second electrode CE2 can include a transparent conductive oxide such as indium tin oxide (ITO) or indium zinc oxide (IZO). The second electrode CE2 can be disposed to be in contact with the cathode electrode 135. The second electrode CE2 can overlap the entire first optical layer 117a, and can overlap a portion of the second optical layer 117b.

The second electrode CE2 can extend continuously in the first direction X of the substrate 110. Accordingly, the second electrode CE2 can be connected in common to at least two pixels PX arranged in the first direction X of the substrate 110. For example, the second electrode CE2 can be connected in common to at least two pixels PX.

The second electrode CE2 can be provided on upper ends of the first optical layer 117a, the second optical layer 117b, and the light emitting device ED. An area in which the first optical layer 117a is disposed can include a concave portion recessed inwardly from the upper surface of the second optical layer 117b. Accordingly, because a first portion of the second electrode CE2 disposed on the first optical layer 117a is disposed along the concave portion, the first portion of the second electrode CE2 disposed on the first optical layer 117a can be disposed at a lower position than a second portion of the second electrode CE2 disposed on the second optical layer 117b.

A third optical layer 117c can be disposed on the second electrode CE2. The third optical layer 117c can be disposed to overlap a plurality of light emitting devices ED and the first optical layer 117a. In this case, the third optical layer 117c does not overlap the second optical layer 117b. Because the third optical layer 117c is disposed on the second electrode CE2 and a plurality of light emitting devices ED, the third optical layer 117c can improve a spot Mura that can occur in some of a plurality of light emitting devices ED. For example, when the plurality of light emitting devices ED is transferred on the substrate 110 of the display panel 100, a region in which a gap between the plurality of light emitting devices ED is not uniform due to a process deviation, or the like can occur. When the gap between the plurality of light emitting devices ED is not uniform, a light emitting area of each of the plurality of light emitting devices ED can be non-uniformly disposed, and thus a spot (or mura) can be recognized by a user. Because the third optical layer 117c for uniformly diffusing light is formed on an upper portion of the plurality of light emitting devices ED, it is possible to reduce visibility of light emitted from some light emitting devices ED as spots (or mura). Therefore, because the light emitted from the plurality of light emitting devices ED is uniformly diffused by the third optical layer 117c and extracted to the outside of the display panel 100, the luminance uniformity of the display apparatus can be improved.

The third optical layer 117c can be formed of an organic insulating material in which fine particles are distributed, but implementations of the present disclosure are not limited thereto. For example, the third optical layer 117c can be formed of siloxane in which fine metal particles such as titanium dioxide (TiO2) particles are distributed. However, the third optical layer 117c can be formed of the same material as the first optical layer 117a. The third optical layer 117c can be referred to as a diffusion layer, an upper diffusion layer, or the like.

Light from the plurality of light emitting devices ED can be scattered by fine particles distributed in the third optical layer 117c and emitted to the outside of the display panel 100. The third optical layer 117c can evenly mix the light emitted from the plurality of light emitting devices ED to further improve luminance uniformity of the display apparatus. In addition, light extraction efficiency of the display apparatus can be improved by the light scattered from the plurality of fine particles, and thus the display apparatus can be driven at a low power.

In the display area AA, a black matrix BM can be disposed on the second electrode CE2, the first optical layer 117a, the second optical layer 117b, and the third optical layer 117c. For example, the black matrix BM can fill a contact hole in the second optical layer 117b. Because the black matrix BM can cover the display area AA, color mixture of light of the plurality of sub-pixels and reflection of external light can be reduced. For example, because the black matrix BM is also disposed within a contact hole in which the second electrode CE2 and the contact electrode CCE are connected to each other, light leakage between the plurality of adjacent sub-pixels can be reduced or prevented.

The black matrix BM is not provided on an upper end of the light emitting device ED. Accordingly, light generated from the light emitting device ED can be output to the outside.

The black matrix BM can be formed of an opaque material, but implementations of the present disclosure are not limited thereto. For example, the black matrix BM can be an organic insulating material to which a black pigment or a black dye is added.

As illustrated in FIG. 8, a cover layer 118 can be disposed on the black matrix BM in the display area AA. The cover layer 118 can protect an device under the cover layer 118. For example, the cover layer 118 can be formed of an organic insulating material, but implementations of the present disclosure are not limited thereto. For example, the cover layer 118 can be formed of a photo resist, polyimide (PI), a photo acryl-based material, or the like. The cover layer 118 can be referred to as an overcoating layer, an insulating layer, or the like.

A polarizing layer 280 can be disposed on the cover layer 118 via a first adhesive layer 291. A cover member 120 can be disposed on the polarizing layer 280 via a second adhesive layer 295. For example, the first adhesive layer 291 and the second adhesive layer 295 can include an optically clear adhesive (OCA), an optically clear resin (OCR), a pressure sensitive adhesive (PSA) or the like, but implementations of the present disclosure are not limited thereto.

According to the present disclosure, the plurality of pad electrodes PE can be disposed on the third insulating layer 115c in the second non-display area NA2. For example, a portion of the plurality of pad electrodes PE can be exposed by the passivation layer 116. For example, the pad electrode PE can be electrically connected to the 2-4th connection line 122d through a contact hole of the third insulating layer 115c.

An adhesive film ACF can be disposed on the plurality of pad electrodes PE. The adhesive film ACF can be an adhesive layer in which conductive balls are distributed in an insulating material. When heat or pressure is applied to the adhesive film ACF, the conductive ball can be electrically connected to the pad electrode in a region to which heat or pressure is applied, and thus the conductive ball can have conductive characteristics. An adhesive film ACF can be disposed between the plurality of pad electrodes PE and the flexible circuit board (or flexible film) 170, so that a flexible circuit board (or flexible film) 170 can be attached to or bonded to the plurality of pad electrodes PE. For example, the adhesive film ACF can be an anisotropic conductive film (ACF).

The flexible circuit board (or flexible film) 170 can be disposed on the adhesive film ACF. The flexible circuit board (or flexible film) 170 can be electrically connected to the plurality of pad electrodes PE through the adhesive film ACF. Therefore, signals output from the flexible circuit board (or flexible film) 170 and the printed circuit board 160 can be transmitted to the pixel driving circuit PD of the display area AA through the pad electrode PE, the 2d-th connection line 122d, the 2c-th connection line 122c, the 2b-th connection line 122b, and the 2a-th connection line 122a.

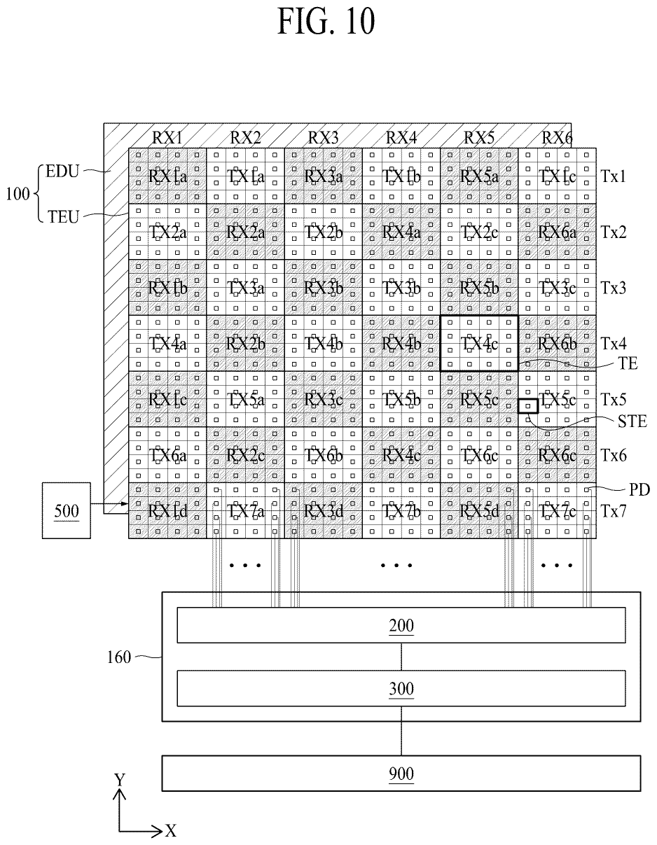

FIG. 10 is an exemplary diagram illustrating a structure of a touch electrode part and a display driver applied to a display apparatus according to an implementation of the present disclosure. In the following descriptions, details that are the same as or similar to details described with reference to FIGS. 1 to 9 are omitted or briefly described.

The display apparatus according to an implementation of the present disclosure, as illustrated in FIG. 10, can include a display panel 100 on which an imaged is displayed and a display driver 200 for supplying image signals and control signals to the pixel driving circuit PD in the display panel 100 during a display period and detecting a touch on the display panel 100 using touch sensing signals transmitted from pixel driving circuits PD provided in the display panel 100 during a touch sensing period.

Also, the display apparatus according to an implementation of the present disclosure can further include a timing controller 300, a power circuit such as power part 500, a memory, etc., as described with reference to FIGS. 1 and 2, in addition to the display panel 100 and the display driver 200. In this case, the display driver 200 can be included in the timing controller 300.

The display driver 200 and the timing controller 300 can be provided on the printed circuit board 160.

The power part 500 can supply power of various levels to the display panel 100, the pixel driving circuit PD, the display driver 200, and the timing controller 300. In particular, the power part 500 can perform a function of supplying a cathode voltage to the second electrode CE2. To this end, the power part 500 can include a cathode voltage supply part 510. However, the cathode voltage supply part 510 can be provided independently of the power part 500.

The power part 500 can generate power required to drive the pixel driving circuit PD and transmit the power to the pixel driving circuit PD. To this end, the power part 500 can include a power supply part 520.

As described above, the display panel 100 can include the substrate 110 including the display area AA and the non-display area NDA, the pixel driving circuits PD provided in the display area on the substrate 110, the insulating layer on the pixel driving circuits PD, the banks BNK on the insulating layer, the first electrodes CE1 connected to the pixel driving circuits PD, the light emitting devices ED provided on the first electrodes, and the second electrodes CE2 provided on the light emitting devices ED.

Here, the insulating layer can be formed as a single layer, but can include a plurality of layers. For example, the insulating layer can include the first insulating layer 115a, the second insulating layer 115b, and the third insulating layer 115c.

The first electrode CE1 can be provided in each of the banks BNK.

The light emitting device ED can be provided on the first electrode CE1.

The second electrode CE2 can be disposed on the light emitting device ED.

Each of the light emitting devices ED can be driven by any one of the pixel driving circuits PD.

Each of the pixel driving circuits PD can be connected to at least two light emitting devices ED to drive at least two light emitting devices ED.

Each of the second electrodes CE2 can be connected to at least two light emitting devices ED.

Some of the plurality of sub-pixels can be covered by the second electrode CE2. For example, the first light emitting device 130, the second light emitting device 140, and the third light emitting device 150 provided in the first sub-pixel SP1, the second sub-pixel SP2, and the third sub-pixel SP3 can be covered by one second electrode CE2.

However, as illustrated in FIGS. 7A and 7B, sub-pixels SP included in two or more pixels PX can be covered by one second electrode CE2.

At least two second electrodes CE2 can be connected to each of the pixel driving circuits PD. For example, when the first light emitting device 130, the second light emitting device 140, and the third light emitting device 150 provided in one pixel PX can be connected to one second electrode CE2. Also, when the pixel driving circuit PD drives at least two pixels PX, at least two second electrodes CE2 can be connected to the pixel driving circuit PD. For example, when the pixels PX arranged in a 16×16 form are connected to the pixel driving circuit PD, 16 second electrodes CE2 can be connected to the pixel driving circuit PD.

In this case, the display panel 100 can include a light emitting device part EDU including pixel driving circuits PD and light emitting devices ED, and a touch electrode part TEU including at least two second electrodes CE2.

For example, in the display panel 100 illustrated in FIG. 8, the substrate 110, the buffer layers 111a and 111b, the adhesive layer 112, the pixel driving circuit PD, the protective layers 113a, 113b and 114, the insulating layers 115a, 115b, and 115c, the first connection line 121, the bank BNK, the first electrodes CE1, the light emitting devices ED, and the optical layers 117a and 117b can be included in the light emitting device part EDU.

In addition, in the display panel 100 illustrated in FIG. 8, the second electrodes CE2 can be included in the touch electrode part TEU.

Also, in the display panel 100 illustrated in FIG. 8, the black matrix BM, the third optical layer 117c, and the cover layer 118 can be other components included in the display panel 100. However, hereinafter, for convenience of description, the black matrix BM, the third optical layer 117c, and the cover layer 118 can be included in the light emitting device part EDU.

To provide an additional description, as described with reference to FIG. 1, the display apparatus 1000 according to an implementation of the present disclosure can include a display panel 100, a polarizing layer 280, an adhesive layer 290, a cover member 120, a support substrate 190, a flexible circuit board 170, and a printed circuit board 160, and the display panel 100 can include various layers as illustrated in FIG. 8.

In this case, various layers included in the display panel 100 can be divided into the light emitting device part EDU and the touch electrode part TEU.

The light emitting device part EDU can include various layers as described above, and in particular, can include light emitting devices ED.

The touch electrode part TEU can include at least two second electrodes CE2.

In this case, the pixel driving circuits PD can be substantially included in the light emitting device part EDU, and can drive the first electrodes CE1 and the second electrodes CE2. However, for convenience of description, in FIG. 10, the pixel driving circuits PD are included in the touch electrode part TEU.

In the following description, the second electrodes CE2 controlled by one pixel driving circuit PD are referred to as a sub-touch electrode STE.

In addition, in the following description, a configuration including at least one sub-touch electrode STE and corresponding to one touch coordinate is referred to as a touch electrode TE.

For example, the sub-touch electrode STE can be connected to the pixel driving circuit PD, and the sub-touch electrode STE can include at least two second electrodes CE2. As described above, when the pixels PX arranged in the form of 16×16 are connected to the pixel driving circuit PD, the sub-touch electrode STE can include 16 second electrodes CE2.

One pixel driving circuit PD controlling one sub-touch electrode STE can be connected to the display driver 200, as illustrated in FIG. 10.

For example, the pixel driving circuit PD can be connected to the display driver 200 through the image signal line IL. Image signals corresponding to the light emitting signals EM to be supplied to the gate of the light emitting transistors TEM provided in the pixel driving circuit PD can be supplied from the display driver 200 to the pixel driving circuit PD through an image signal line. Also, a touch sensing signal line through which a touch sensing signal is transmitted can be further provided between the pixel driving circuit PD and the display driver 200.

Hereinafter, for convenience of description, a display apparatus according to the present disclosure will be described by taking as an example a touch electrode TE including four sub-touch electrodes STE provided along the first direction X and four sub-touch electrodes STE provided along the second direction Y, as illustrated in FIG. 10. However, depending on the structure or resolution of the display panel 100, the touch electrode TE provided on the left side of the display panel 100 or the touch electrode TE provided on the right side can include three sub-touch electrodes STE provided along the first direction X and four sub-touch electrodes STE provided along the second direction Y. For example, in the display panel 100, each of the touch electrodes TE provided on the right side or the left side of the display panel 100 can include three sub-touch electrodes STE provided along the first direction X and four sub-touch electrodes STE provided along the second direction Y.

To provide an additional description, in the following description, the touch electrode TE, as illustrated in FIG. 10, can include 16 sub-touch electrodes STE. However, the number of sub-touch electrodes STE included in the touch electrode TE can be variously changed based.

In this case, the display driver 200 can include a data driver that generates image signals to be supplied to the pixel driving circuit PD and a touch driver for sensing a touch.

For example, the display driver 200 can generate image signals to be supplied to the pixel driving circuit PD and supply the image signals to the pixel driving circuit PD.

To this end, each of the pixel driving circuits PD corresponding to all the sub-touch electrodes STE included in the touch electrode part TEU can be connected to the display driver 200 through the image signal line.

In this case, power required by the pixel driving circuit PD can be transmitted from the power part 500 to the pixel driving circuit PD through the display driver 200 or can be directly transmitted from the power part 500 to the pixel driving circuit PD. Hereinafter, as illustrated in FIG. 10, a display apparatus according to the present disclosure will be described by taking as an example a display apparatus in which the power part 500 supplies power to the pixel driving circuit PD.

Furthermore, the cathode voltage required to drive the light emitting device ED can be transmitted from the cathode voltage supply part 510 to the pixel driving circuit PD through the display driver 200, or can be transmitted directly from the cathode voltage supply part 510 to the pixel driving circuit PD. Hereinafter, for convenience of description, a display apparatus in which the cathode voltage is directly transmitted from the cathode voltage supply part 510 included in the power part 500 to the pixel driving circuit PD and power is directly transmitted from the power supply part 520 included in the power part 500 to a sensing circuit, such as sensing part 440, of the pixel driving circuit PD will be described as an example of the display apparatus according to the present disclosure.

Furthermore, the display driver 200 can detect a touch on the display panel 100 by using a touch sensing signal received from the pixel driving circuit PD.

In this case, the touch coordinates can be determined by the display driver 200, or can be determined by the timing controller 300 or the external system 900.

First, the structure and function of the display panel 100 will be described as follows. Hereinafter, details that are the same as or similar to those described with reference to FIGS. 1 to 9 will be omitted or briefly described.

The display panel 100 can include a light emitting device part EDU including pixel driving circuits PD and light emitting devices ED, and a touch electrode part TEU including at least two second electrodes CE2.

Light can be output from the light emitting device part EDU, and accordingly, an image can be displayed.

The touch electrode part TEU includes at least two touch electrodes TE. The touch electrode TE can include at least one sub-touch electrode STE, and can correspond to one touch coordinate.

The touch electrode TE can include at least two second electrodes CE2 connected to the pixel driving circuit PD. The second electrodes CE2 controlled by one pixel driving circuit PD are referred to as sub-touch electrodes STE.

Each of the at least two second electrodes CE2 can extend along a first direction X of the substrate 110, and at least two second electrodes CE2 can be provided along a second direction Y different from the first direction X.

When a cathode voltage is supplied to any one of the at least two second electrodes CE2, light can be output from light emitting devices ED connected to second electrode CE2 to which the cathode voltage is supplied.

For example, a period in which an image is displayed on the display panel 100 is referred to as a display period, and during the display period, a cathode voltage can be supplied to the cathode electrode 135 through the second electrode CE2. The light emitting device ED can output light using a cathode voltage supplied through the cathode electrode 135 and an anode voltage supplied to the anode electrode 134.

When at least two second electrodes CE2 are used as one touch electrode TE, a touch driving signal can be simultaneously supplied to the at least two second electrodes CE2.

For example, a period during which a touch is detected on the display panel 100 is referred to as the touch sensing period, and during the touch sensing period, each of the pixel driving circuits PD can simultaneously supply a touch driving signal to the second electrodes CE2. In this case, the display driver 200 can detect a touch on the display panel 100 by using touch sensing signals received through the pixel driving circuit PD from the second electrodes CE2.

Second, the structure and function of the pixel driving circuit PD will be described as follows. Hereinafter, details that are the same as or similar to those described with reference to FIGS. 1 to 9 will be omitted or briefly described.

In the display period in which an image is displayed, image signals corresponding to light emitting signals EM to be supplied to a gate of light emitting transistors TEM provided in the pixel driving circuit PD can be supplied to the pixel driving circuit PD through the image signal line.

Image signals generated by the display driver 200 are transmitted to the pixel driving circuit PD through the image signal line, and the pixel driving circuit PD can generate light emitting signals EM by using the image signals. Accordingly, light can be output from the light emitting devices ED.

In addition, the display driver 200 can transmit image signals to each of the image signal lines during the display period. During the touch sensing period in which a touch is detected, touch sensing signals transmitted from the second electrodes CE2 can be transmitted to the display driver 200 through a touch sensing signal line.

For example, during the touch sensing period, the pixel driving circuit PD can supply the touch driving signal to the second electrodes CE2 and transmit the touch sensing signal received from the second electrodes CE2 to the display driver 200 through a touch sensing signal line. This touch sensing method is referred to as a self-capacitance method.

The function as described above can be performed simultaneously in each of the pixel driving circuits PD.

In this case, the touch driving signal can be generated in the pixel driving circuit PD, or can be generated in the display driver 200 and transmitted to the pixel driving circuit PD. However, hereinafter, for convenience of description, a display apparatus in which a touch driving signal is generated in the pixel driving circuit PD will be described as an example of a display apparatus according to the present disclosure.

Third, as described above, in a display apparatus using the self-capacitance method, each of the touch electrodes TE illustrated in FIG. 10 can be independently driven, and one touch coordinate can correspond to each of the touch electrodes TE.

For example, in a display apparatus using the self-capacitance method, the pixel driving circuit PD can transmit a touch driving signal to the second electrodes CE2 and receive a touch sensing signal from the second electrodes CE2. The touch sensing signal can be converted into a digital signal and transmitted to the display driver 200.

In this case, if there is no touch on the touch electrode TE, the value of the touch sensing signals received from the pixel driving circuits PD corresponding to the touch electrode TE can have a value in a preset range. However, when there is a touch on the touch electrode TE, the value of the touch sensing signals received from the pixel driving circuits PD corresponding to the touch electrode TE can have a value outside a preset range. Using this difference, the display driver 200 can detect a touch on the touch electrode TE.

However, in a display apparatus according to an implementation of the present disclosure, a touch can be detected using a mutual-capacitance method.

For example, in a display panel 100 to which the mutual-capacitance method is applied, as illustrated in FIG. 10, first sub-driving electrodes TX1a, TX1b, and TX1c forming a first driving electrode TX1 and sub-receiving electrodes RX1a, RX3a, and RX5a forming receiving electrodes RX can be alternately provided at the top of the display panel 100.

Second sub-driving electrodes TX2a, TX2b, and TX2c forming a second driving electrode TX2 and sub-receiving electrodes RX2a, RX4a, and RX6a forming receiving electrodes RX can be alternately provided below the first driving electrode TX1.

In this case, the first sub-driving electrodes TX1a, TX1b, and TX1c and the second sub-driving electrodes TX2a, TX2b, and TX2c are not provided on a straight line in the second direction Y, but are staggered in diagonal directions. Accordingly, the sub-driving electrodes and the sub-receiving electrodes are provided alternately in the second direction Y.

Due to the above-described arrangement structure, seventh sub-driving electrodes TX7a, TX7b, and TX7c forming a seventh driving electrode TX7 and sub-receiving electrodes RX1d, RX3d, and RX5d forming receiving electrodes RX can be alternately provided at the lowermost part of the display panel 100.

In this case, each of the sub-driving electrodes and the sub-receiving electrodes can correspond to the touch electrode TE in the self-capacitance method, and can correspond to one touch coordinate.

For example, each of the sensing parts 440 included in the pixel driving circuits PD corresponding to the sub-driving electrodes during the touch sensing period can supply a touch driving signal to the second electrodes CE2.

In this case, each of the sensing parts 440 included in the pixel driving circuits PD corresponding to the sub-receiving electrodes can convert an analog-type touch sensing signal received from the second electrodes CE2 into a digital-type touch sensing signal and transmit the digital-type touch sensing signal to the display driver 200.

The display driver 200 can detect a touch on the display panel 100 by using touch sensing signals received from the pixel driving circuits PD corresponding to one sub-receiving electrode.

For example, when a touch occurs at the 2b-th sub-driving electrode TX2b among the 2nd sub-driving electrodes TX2a, TX2b, and TX2c forming the second driving electrode TX2, the value of the touch sensing signals corresponding to the 2a-th sub-receiving electrode RX2a among the 2nd sub-receiving electrodes RX2a, RX2b, and RX2c forming the second receiving electrode RX2 can be out of the range of touch sensing signals when there is no touch, and the value of the touch sensing signals corresponding to the 4a-th sub-receiving electrode RX4a among the 4th sub-receiving electrodes RX4a, RX4b, and RX4c forming the fourth receiving electrode RX4 can be out of the range of touch sensing signals when there is no touch.

Accordingly, the display driver 200 can determine that a touch has occurred in the 2b-th sub-driving electrode TX2b provided between the 2a-th sub-receiving electrode RX2a and the 4a-th sub-receiving electrode RX4a.

For example, when the touch driving signal is transmitted to the sub-driving electrode where the touch occurs, the value of the touch sensing signals received from the sub-receiving electrode adjacent to the sub-driving electrode where the touch occurs can be out of the reference range when there is no touch. Accordingly, the display driver 200 can determine the position of the sub-driving electrode where the touch occurs using this difference.

As another example, when a touch occurs at the sub-receiving electrode, the value of the touch sensing signals received from the pixel driving circuits corresponding to the sub-receiving electrode where the touch occurs can be different from the value of the touch sensing signals received from the pixel driving circuits corresponding to the sub-receiving electrode where the touch does not occur. Therefore, the display driver 200 can use this difference to determine the location of the sub-receiving electrode where the touch occurs.

In addition, even if the sub-driving electrodes and sub-receiving electrodes do not overlap in the thickness direction of the display panel 100 and are disposed adjacent to each other on the plane of the display panel 100, as illustrated in FIG. 10, touch driving signals transmitted to the sub-driving electrodes can affect the adjacent sub-receiving electrodes. In this case, touch sensing signals corresponding to touch driving signals can be generated from the sub-receiving electrodes. Accordingly, the display driver 200 can detect a touch on the display panel 100 by analyzing values of the touch sensing signals.

Fourth, as described above, in a display apparatus 1000 according to an implementation of the present disclosure, a touch can be detected using a self-capacitance method, and a touch can be detected using a mutual-capacitance method.

Also, a touch can be detected using a self-capacitance method and a mutual-capacitance method.

For example, during a first touch sensing period, the pixel driving circuits PD provided in each of the touch electrodes TE can supply a touch driving signal to the second electrodes CE2 and transmit the touch sensing signal received from the second electrodes CE2 to the display driver 200. In this case, the display driver 200 can detect a touch in each of the touch electrodes TE by using the received touch sensing signals.

In this case, during a second touch sensing period, the pixel driving circuits PD included in the touch electrodes TE corresponding to the sub-driving electrodes among the touch electrodes TE can supply a touch driving signal to the second electrodes CE2, and the pixel driving circuits PD included in the touch electrodes TE corresponding to the sub-receiving electrodes among the touch electrodes TE can receive an analog-type touch sensing signal from the second electrodes CE2, convert the received analog-type touch sensing signal into a digital-type touch sensing signal, and then transmit the converted touch sensing signal to the display driver 200. In this case, the display driver 200 can detect a touch in each of the touch electrodes TE using the method described above.

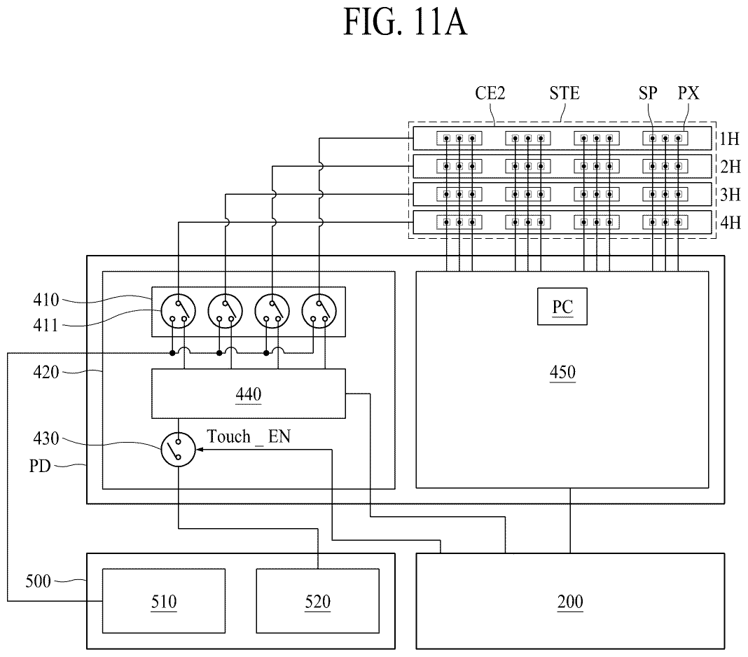

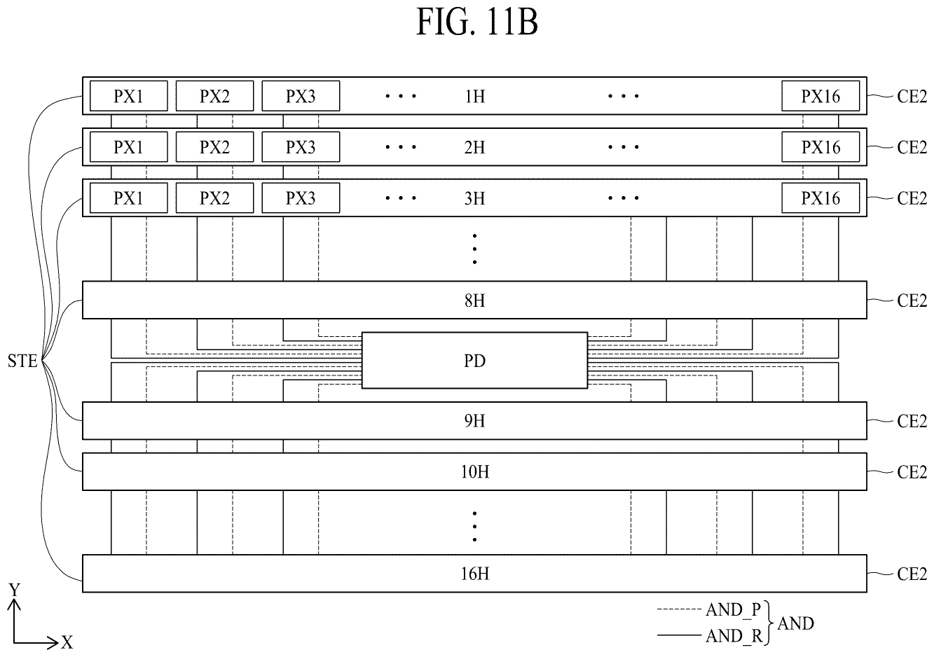

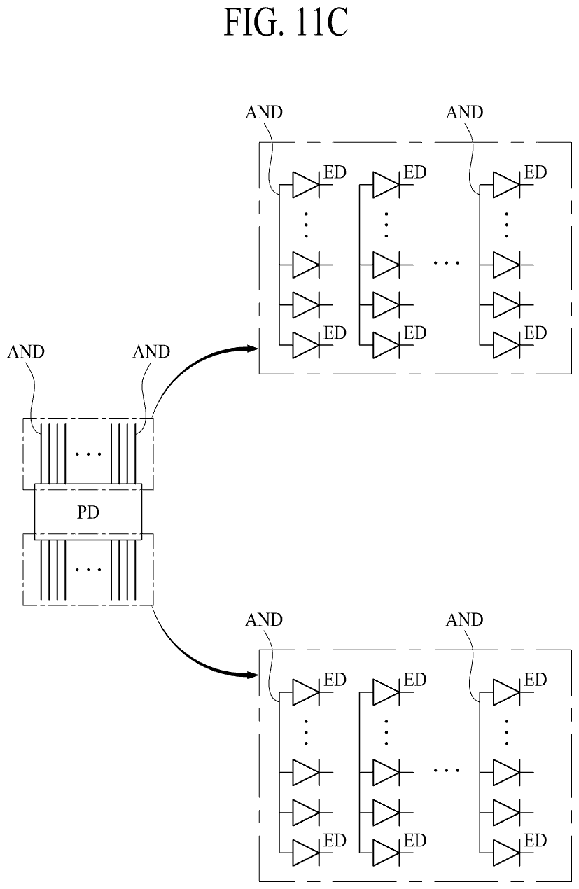

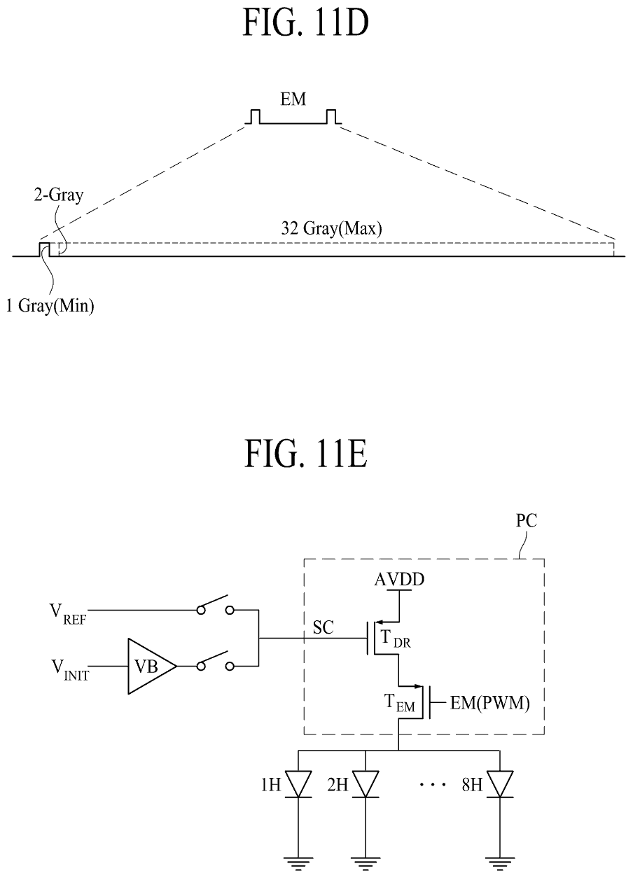

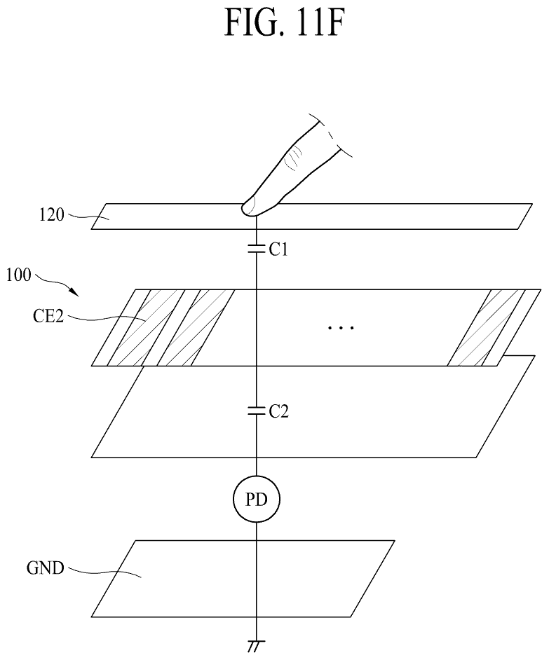

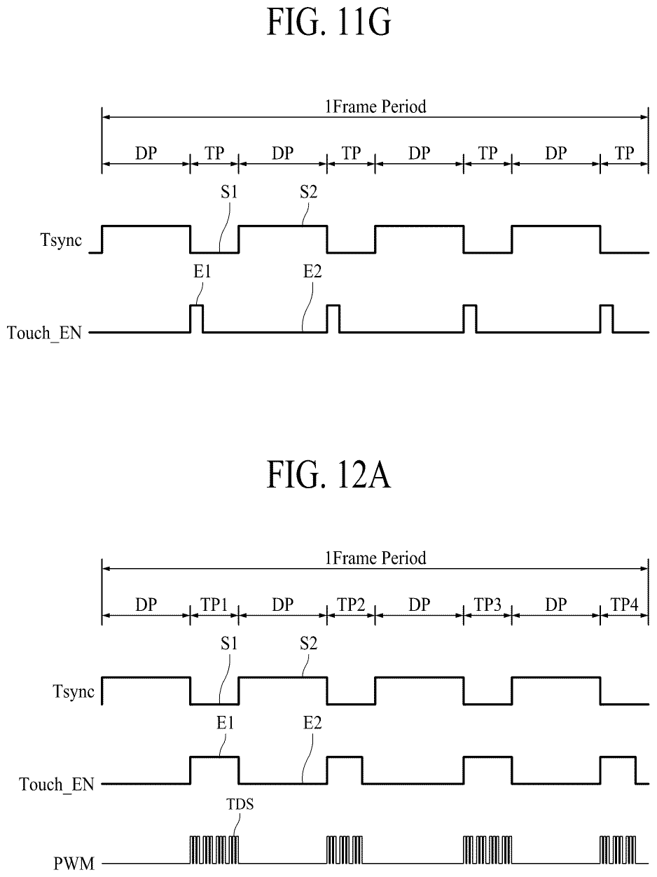

FIG. 11A is an exemplary diagram illustrating structures of a sub-touch electrode and a pixel driving circuit applied to a display apparatus according to an implementation of the present disclosure, FIG. 11B is an exemplary diagram illustrating a connection structure of a sub-touch electrode and a pixel driving circuit applied to a display apparatus according to an implementation of the present disclosure, and FIG. 11C is an exemplary diagram illustrating a connection relationship between a pixel driving circuit and light emitting devices applied to a display apparatus according to an implementation of the present disclosure.

In the following descriptions, details that are the same as or similar to details described with reference to FIGS. 1 to 10 will be omitted or briefly described.

As illustrated in FIG. 11A, the pixel driving circuit PD can include a sub-pixel driving part 450 for supplying anode voltages to anode electrodes 134 provided in the sub-pixels SP and a cathode electrode driving part 420 for supplying a cathode voltage or a touch driving signal to a second electrode CE2 shared in at least two sub-pixels SP.

As described above, the second electrodes CE2 controlled by one pixel driving circuit PD are referred to as sub-touch electrode STE.

The sub-touch electrode STE can include at least two second electrode CE2.

As described above, at least two light emitting devices ED can be connected to one pixel driving circuit PD. In addition, one second electrode CE2 can be connected to at least two light emitting devices ED.

Hereinafter, for convenience of description, a display apparatus including a pixel driving circuit PD to which 16 pixels PX having a 4×4 shape are connected, as illustrated in FIG. 11A, is described as an example of a display apparatus according to an implementation of the present disclosure. In addition, in the display apparatus illustrated in FIG. 11A, pixels PX arranged in a 4×4 shape are connected to the pixel driving circuit PD, but in the display apparatus according to an implementation of the present disclosure, pixels PX arranged in a 4N×4M (N and M are natural numbers) form can be connected to the pixel driving circuit PD. For example, in FIG. 11B, pixels PX arranged in a 16×16 shape are connected to the pixel driving circuit PD.

For example, as illustrated in FIG. 11A, the pixel driving circuit PD can be connected to four pixels PX provided along the first direction X and four pixels PX provided along the second direction Y.

In this case, one second electrode CE2 controlled by the pixel driving circuit PD can be connected to the light emitting devices DE provided in at least two sub-pixels SP.

In particular, the second electrode CE2 can be connected to at least two light emitting devices DE provided along the first direction X of the display panel 100, and at least two second electrodes CE2 provided along the second direction Y can be separated from each other.

When four pixels PX are provided along the first direction X, and one pixel PX includes three sub-pixels SP, 12 sub-pixels PX can be provided along the first direction X.

In this case, when the second electrode CE2 provided along the first direction X is shared by the two sub-pixels SP, six second electrodes CE2 can be provided along the first direction X.

Accordingly, one pixel driving circuit PD can be connected to 24 (=6×4) second electrodes CE2.

However, hereinafter, for convenience of description, as illustrated in FIG. 11A, the display apparatus according to an implementation of the present description will be described by taking as an example a display apparatus in which four pixels PX provided along the first direction X are connected to one second electrode CE2.

In this case, the pixel driving circuit PD can be connected to the four second electrodes CE2.

Hereinafter, for convenience of description, a display apparatus according to an implementation of the present disclosure is described using a pixel driving circuit PD to which 16 pixels PX having a 4×4 shape are connected and a second electrode CE2 connected to four pixels PX along the first direction X, as illustrated in FIG. 11A.

First, the sub-pixel driving part 450 will be described as follows.

Hereinafter, as illustrated in FIGS. 4 and 11A, a circuit provided in the sub-pixel driving part 450 for driving at least one light emitting device ED is referred to as a pixel circuit PC. For example, the pixel circuit PC can include a driving transistor TDR and a light emitting transistor TEM, as illustrated in FIG. 4. In this case, a scan signal SC capable of turning on the driving transistor TDR can be supplied to a gate of the driving transistor TDR. The scan signal SC can be a direct current power source capable of continuously turning on the driving transistor TDR. For example, a fixed reference voltage Vref can be supplied to the gate of the driving transistor TDR for each frame.

A light emitting signal EM can be supplied to the gate of the light emitting transistor TEM. The light emitting signal EM can be a pulse width modulation (PWM) signal. The amount of current supplied to the light emitting device ED can be controlled by the light emitting signal EM, and thus, light having various brightness can be output from the light emitting device ED. At least one pixel circuit PC can be provided in the sub-pixel driving part 450.

In this case, a high potential power supply voltage VDD can be supplied to the first electrode of the driving transistor TDR provided in the pixel circuit PC. The high potential power supply voltage VDD can be supplied from a power part 500 provided outside the pixel driving circuit PD.

The scan signal SC and the light emitting signal EM can be transmitted from a control signal generation part provided outside the pixel driving circuit PD. For example, the scan signal SC and the light emitting signal EM can be transmitted from a control signal generation part included in the timing controller 300. In this case, the light emitting signal EM can be generated in the sub-pixel driving part 450 by using image signals transmitted from the timing controller 300.

For example, as illustrated in FIG. 11A, when four pixels PX connected to the pixel driving circuit PD are provided in one row extending along the first direction X, 16 pixels PX can be provided in four rows 1H, 2H, 3H, and 4H.

To provide an additional description, each of the four rows can be provided along the first direction X, and the four rows can be spaced apart along the second direction Y.

In this case, in order to output light from the light emitting devices ED provided in the first row 1H, light emitting signals EM and scan signals can be supplied to pixel circuits PC connected to the light emitting devices ED provided in the first row 1H.

As described above, the scan signal SC can be a direct current (DC) power source capable of continuously turning on the driving transistor TDR, and the light emitting signal EM can be a pulse width modulation (PWM) signal.

The light emitting transistor TEM can be turned on by the scan signal SC, and thus, the high potential power supply voltage VDD can be supplied to the anode electrode 134 of the light emitting device ED through the driving transistor TDR, the light emitting transistor TEM, and the first electrode CE1.

In this case, as described above, the light emitting signal EM applied to the gate electrode of the light emitting transistor TEM can be a pulse width modulation (PWM) signal, and the pulse width of the light emitting signals EM supplied to the pixel circuits PC connected to the anode electrodes 134 of the light emitting devices ED provided in the first row 1H can be variously set depending on the brightness of light output from the light emitting devices ED.

For example, the pulse width of the light emitting signal EM supplied to the pixel circuit PC connected to the light emitting device outputting high-brightness light can be greater than the pulse width of the light emitting signal EM supplied to the pixel circuit PC connected to the light emitting device outputting low-brightness light.

In this case, when a high-level pulse is supplied to the gate of the light emitting transistor TEM, the light emitting transistor TEM can be turned on.

When the period in which the light emitting transistor TEM is turned on increases, the amount of current supplied to the light emitting device ED through the light emitting transistor TEM can increase. The luminance of the light emitting device ED can vary based on the magnitude of the current flowing to the light emitting device ED.

Therefore, as the pulse width of the light emitting signal EM increases, the luminance of light output from the light emitting device ED can increase.

Also, when the pulse width of the light emitting signal EM supplied to the pixel circuit PC connected to the light emitting device outputting high-brightness light and the pulse width of the light emitting signal EM supplied to the pixel circuit PC connected to the light emitting device outputting low-brightness light are the same, the number of pulses of the light emitting signal EM supplied to the pixel circuit PC connected to the light emitting device outputting high-brightness light can be greater than the number of pulses of the light emitting signal EM supplied to the pixel circuit PC connected to the light emitting device outputting low-brightness light. For example, the frequency of the light emitting signal EM supplied to the pixel circuit PC connected to the light emitting device outputting high-brightness light can be greater than the frequency of the light emitting signal EM supplied to the pixel circuit PC connected to the light emitting device outputting low-brightness light.

When the frequency increases, the number of pulses increases. When the number of pulses supplied to the light emitting transistor TEM increases, the number of times the light emitting transistor TEM is turned on increases. When the number of times the light emitting transistor TEM is turned on increases, the amount of current flowing to the light emitting device ED through the light emitting transistor TEM can increase.

As described above, because the luminance of the light emitting device ED can be changed depending on the magnitude of the current flowing to the light emitting device ED, as the frequency of the light emitting signal EM increases or the number of pulses of the light emitting signal EM increases, the luminance of light output from the light emitting device ED can increase.

For example, the timing controller 300 or the sub-pixel driving part 450 can supply light emitting signals EM with different frequencies or different pulse widths to the light emitting transistor TEM provided in the pixel circuit PC.

Accordingly, light having different luminance can be output from the light emitting devices ED connected to the pixel driving circuit PD.

Second, the cathode electrode driving part will be described as follows.

When the scan signal SC is supplied to the driving transistor TDR, the cathode electrode driving part 420 can supply cathode voltages to the second electrodes CE2.

For example, as illustrated in FIG. 11A, when 16 pixels PX having a 4×4 shape are connected to the pixel driving circuit PD and one second electrode CE2 is connected to four pixels PX provided along the first direction X, 16 pixels PX can be provided in four rows 1H, 2H, 3H, and 4H, and the four rows 1H, 2H, 3H, and 4H can be spaced apart from each other along the second direction Y.

In this case, four pixels PX provided in each of the four rows 1H, 2H, 3H and 4H are connected to one second electrode CE2. Accordingly, four second electrodes CE2 are provided in the display panel 100 for driving the 16 pixels PX.

The four second electrodes CE2 are connected to one pixel driving circuit PD. The four second electrodes CE2 connected to one pixel driving circuit PD are referred to as sub-touch electrodes STE. For example, the sub-touch electrode STE include four second electrodes CE2.

To provide an additional description, at least one second electrode CE2 connected to the pixel driving circuit PD can be provided along the first direction X or row of the display panel 100, and at least two light emitting devices ED connected to the second electrode CE2 can be provided in a row along the first direction X or row.

In the above example, three sub-pixels SP are provided in each of the four pixels PX provided in the first row 1H.

Accordingly, when anode voltages are supplied from the 12 pixel circuits PC connected to the 12 sub-pixels SP provided in the first row 1H to the 12 anode electrodes 134 provided in the 12 sub-pixels SP, the cathode electrode driving part 420 can supply a cathode voltage to the second electrodes CE2 in the first row 1H. Accordingly, light can be output from the sub-pixels SP provided in the first row 1H.

This operation can be concurrently (or in some implementations, simultaneously) performed in sub-pixels SP provided in the first row 1H and connected to other pixel driving circuits PD. Accordingly, light can be concurrently output from all sub-pixels SP provided in the first row 1H of the display panel 100.

Also, when anode voltages are supplied from the 12 pixel circuits PC connected to the 12 sub-pixels SP provided in the second row 2H to the 12 anode electrodes 134 provided in the 12 sub-pixels SP, the cathode electrode driving part 420 can supply a cathode voltage to the second electrodes CE2 provided in the second row 2H. Accordingly, light can be output from the sub-pixels SP provided in the second row 2H.

This operation can be concurrently performed in sub-pixels SP provided in the second row 2H and connected to other pixel driving circuits PD. Accordingly, light can be concurrently output from all sub-pixels SP provided in the second row 2H of the display panel 100.

By the above-described operations, light can be sequentially output from sub-pixels SP provided in all rows of the display panel 100, and thus, one image can be displayed through the display panel 100.

The sub-pixels SP can be individually driven by the structure and driving method as described above.

In order to perform the operation as described above, the cathode electrode driving part 420, as illustrated in FIG. 11A, can include a sensing part 440 for supplying a cathode voltage or a touch driving signal to the second electrodes CE2, a sensing switch 430 for transmitting power transmitted from the power part 500 to the sensing part 440 or blocking the power transmitted from the power part 500 depending on a touch enable signal, and a control switching part 410 for supplying a cathode voltage to the second electrodes CE2 during the display period and connecting the sensing part to the second electrodes CE2 during the touch sensing period.

The control switching part 410 includes control switches 411. Each of the control switches 411 can connect the second electrode CE2 to the sensing part 440 or the cathode voltage supply part 510.

The cathode voltage supply part 510 can generate a cathode voltage. The cathode voltage supply part 510 can be provided independently of the power part 500, but can be included in the power part 500 as illustrated in FIG. 11A.

Each of the control switches 411 can connect the second electrode CE2 to the cathode voltage supply part 510 or to the sensing part 440 in response to a control signal transmitted from the display driver 200 or the timing controller 300.

For example, the control switch 411 can connect the second electrode CE2 to the cathode voltage supply part 510 during the display period, and the second electrode CE2 to the cathode voltage supply part 510 during the touch sensing period.

In particular, the control switching part 410 can sequentially supply cathode voltages to the second electrodes CE2 during the display period, and simultaneously supply touch driving signals to the second electrodes CE2 during the touch sensing period. To this end, the control switching part 410 can be formed in various structures.

Each of the control switches 411 can be turned on or off by a control signal received from the timing controller 300 or the display driver 200. The control signal can include a touch synchronization signal to be described below.

In the above example, one sub-touch electrode STE includes four second electrodes CE2, and the four second electrodes CE2 are connected to one pixel driving circuit PD.

In this case, the control switching part 410 can include four control switches 411. Each of the four control switches 411 is connected to the second electrode CE2, the cathode voltage supply part 510, and the sensing part 440.

During the display period in which an image is displayed on the display panel 100, the control switch 411 can connect the second electrode CE2 to the cathode voltage supply part 510.

For example, each of the pixel driving circuits PD can supply a cathode voltage to at least one second electrode CE2 provided along the first direction X or row of the display panel 100 during the display period.

In the above example, one second electrode CE2 is provided in one row. Accordingly, the control switch 411 can connect one second electrode CE2 provided in one row to the cathode voltage supply part 510 during the display period. In this case, the control switch 411 is turned on, and thus the second electrode CE2 can be connected to the cathode voltage supply part 510. Accordingly, the second electrode CE2 can be connected to the cathode voltage supply part 510 through the control switch 411.

However, when two or more second electrodes CE2 are provided in one row, the control switch 411 can connect two or more second electrodes CE2 provided in one row to the cathode voltage supply part 510.

As described above, when an anode voltage is supplied from the sub-pixel driving part 450 to the anode electrode 134 of the light emitting device ED through the first electrode CE1, and a cathode voltage is supplied from the cathode electrode driving part 420 to the cathode electrode 135 of the light emitting device ED through the second electrode CE2, light can be output from the light emitting device ED.

When the cathode voltage is sequentially supplied to the four second electrodes CE2 provided in the four rows 1H, 2H, 3H, and 4H, light can be sequentially output from the four rows 1H, 2H, 3H, and 4H.

The same operation can be performed in the sub-pixels SP connected to other pixel driving circuits PD.

Accordingly, light can be sequentially output from the rows of the display panel 100, and thus, one image can be displayed throughout the display panel 100.

Also, during the touch sensing period in which a touch is detected in the display panel 100, all of the control switches 411 can connect all of the second electrode CE2 to the sensing part 440. In this case, all of the control switches 411 can be turned.

The display period for displaying an image and the touch sensing period for sensing a touch can be implemented in a time division method.

For example, each of the pixel driving circuits PD can supply a touch driving signal to all the second electrodes CE2 connected to the pixel driving circuit PD during the touch sensing period.

In the above example, one second electrode CE2 is provided in one row, and four second electrodes CE2 are provided in four rows. Accordingly, the control switching part 410 can connect all four second electrodes CE2 to the sensing part 440 during the touch sensing period. In this case, the touch driving signal output from the display driver 200 or the sensing part 440 can be transmitted to the second electrode CE2 through the control switch 411. Also, the touch sensing signal generated from the second electrode CE2 can be transmitted to the display driver 200 through the control switch 411.

When two or more second electrodes CE2 are provided in one row, the control switch 411 can connect the two or more second electrodes CE2 in one row to the sensing part 440.

When the touch driving signal is concurrently supplied to the four second electrodes CE2 provided in the four rows 1H, 2H, 3H, and 4H, a touch sensing signal can be generated in the four rows.

The touch sensing signal generated in the four rows can be transmitted to the display driver 200 through the control switching part 410 and the sensing part 440. In this case, the sensing part 440 can convert an analog-type touch sensing signal transmitted through the control switching part 410 into a digital-type touch sensing signal to transmit the digital-type touch sensing signal to the display driver 200. Hereinafter, the analog-type touch sensing signal and the digital-type touch sensing signal are collectively referred to as a touch sensing signal. The operation can be similarly performed in other pixel driving circuits PD.

In addition, each of the sensing part 440 provided in each of the pixel driving circuits PD can supply a touch driving signal to at least one second electrode CE2 during the touch sensing period, and transmit a touch sensing signal received from at least one second electrode to the display driver 200.

The display driver 200 can determine whether there is a touch on the touch electrode TE by using the touch sensing signal transmitted from the at least one pixel driving circuit PD.

In the above, a driving method in a display apparatus using the self-capacitance method has been described, but the driving method described above can also be applied to a display apparatus using the mutual-capacitance method and a display apparatus using both the self-capacitance method and the mutual-capacitance method.

For example, the driving method of the pixel driving circuit PD provided in the display apparatus using the self-capacitance method in the display period can be applied equally to the driving method of the pixel driving circuit PD provided in the display apparatus using the mutual-capacitance method in the display period.

The driving method of the pixel driving circuit PD provided in the display apparatus using the mutual-capacitance method in the touch sensing period can vary depending on whether the pixel driving circuit PD is included in the sub-driving electrode or the sub-receiving electrode, as described above.

The sensing switch 430 can be connected between the power part 500 and the sensing part 440, and supply power to the sensing part 440 or block power supplied to the sensing part 440.

The power part 500 can include a cathode voltage supply part 510 for generating a cathode voltage and a power supply part 520 for generating power required to drive the sensing part 440. The power supply part 520 can generate various power for driving the display apparatus as well as the sensing part 440.

The display driver 200 can transmit a touch enable signal Touch_EN as illustrated in FIG. 11G to the sensing switch 430. The display driver 200 can generate various types of touch enable signals Touch_EN depending on the structure of the touch electrodes TE, a method of sensing a touch, and the number of touch electrodes TE.

The sensing switch 430 is turned on or off depending on the touch enable signal Touch_EN.

For example, during the display period in which the cathode voltage is supplied from the cathode voltage supply part 510 to the second electrode CE2 through the control switching part 410, the sensing switch 430 can be turned off by the touch enable signal Touch_EN. Accordingly, the sensing part 440 is not driven during the display period.

However, during the touch sensing period, the sensing switch 430 can be turned on by the touch enable signal Touch_EN, and accordingly, power can be supplied from the power supply part 520 to the sensing part 440.

Accordingly, the sensing part 440 can be driven, and accordingly, the touch driving signal can be supplied to the second electrodes CE2, and the touch sensing signal can be transmitted to the display driver 200.

In particular, in a display apparatus according to an implementation of the present disclosure, the sensing switch 430 can be turned on only during a period in which the touch driving signal is supplied to the second electrodes CE2, in the touch sensing period. For example, even in the touch sensing period, the sensing switch 430 can be turned off during a period in which the touch driving signal is not supplied to the second electrodes CE2.

For example, power can be supplied to the sensing part 440 only during the minimum period for sensing a touch. Accordingly, power consumption of the sensing part 440 can be reduced or minimized, and thus power consumption of the pixel driving circuit PD can be reduced or minimized, and finally, power consumption of the display apparatus can be reduced or minimized.

Third, as described above, in the display apparatus according to an implementation of the present disclosure, pixels PX arranged in a 4×4 form as illustrated in FIG. 11A can be connected to the pixel driving circuit PD, pixels PX arranged in a 16×16 form as illustrated in FIG. 11B can be connected to the pixel driving circuit PD, or pixels PX arranged in various forms can be connected to the pixel driving circuit PD. Hereinafter, a structure of a display panel 100 applied to a display apparatus according to an implementation of the present disclosure will be described with reference to FIGS. 11B and 11C. In the following descriptions, details that are the same as or similar to details described with reference to FIGS. 1 to 11A will be omitted or briefly described. In a display apparatus according to an implementation of the present disclosure, a pixel driving circuit PD and pixels PX1 to PX16 including light emitting devices ED electrically connected to the pixel driving circuit PD can be provided.

For example, as illustrated in FIG. 11B, the first to sixteenth pixels PX1 to PX16 can be arranged along the first direction X. A pixel PX can include a red sub-pixel, a green sub-pixel, and a blue sub-pixel SP.

A light emitting device ED can be disposed in the sub-pixel SP. At least one light emitting device ED can be disposed in one sub-pixel SP. For example, two light emitting devices can be disposed in one sub-pixel. One of the two light emitting devices can be a main light emitting device, and the other can be a redundancy light emitting device. The light emitting device ED can be a micro LED.

A red sub-pixel, a green sub-pixel, and a blue sub-pixel can be repeatedly disposed along the first direction X.

Sub-pixels SP that output light of the same color can be disposed along the second direction Y. For example, along the second direction Y, sub-pixels SP that output light of any one color of red, green, and blue can be disposed. The sub-pixels SP emitting the same color can be electrically connected through one first electrode line AND, as illustrated in FIG. 11C. The first electrode line AND can be connected to the first electrodes CE1.

The first electrode line AND can include a first line AND_P and a second line AND_R. The first line AND_P and the second line AND_R can be disposed to be spaced apart from each other in the first direction X. The first line AND_P can be connected to the main light emitting device, and the second line AND_P can be connected to the redundancy light emitting device.

Each of the second electrodes CE2 can extend in the first direction X, as illustrated in FIG. 11B. Also, each of the second electrodes CE2 can be arranged to be spaced apart from each other along the second direction Y. Accordingly, each of the second electrodes CE2 can be connected to the first to sixteenth pixels PX1 to PX16 disposed in each of the rows 1H to 16H.

The pixel driving circuit PD can be connected to the pixels PX1 to PX16 through the first electrodes CE1 and the second electrodes CE2. Accordingly, the pixel driving circuit PD can drive the light emitting devices ED arranged in the first to sixteenth rows 1H to 16H.

To provide an additional description, the pixel driving circuit PD can be electrically connected to the light emitting devices arranged in the first to 16th rows 1H to 16H through the first electrodes CE1 and the second electrodes CE2, and the pixel driving circuit PD can supply the control signal and power to the light emitting devices ED through the first electrodes CE1 and the second electrodes CE2 to control the light emitting operation of the light emitting devices ED.

In this case, the second electrodes CE2 can be connected to the pixels PX and the pixel driving circuit PD in the form illustrated in FIG. 11B, the first electrodes CE1 provided in the pixels PX can be connected to the first electrode lines AND in the form illustrated in FIG. 11C, and the first electrodes CE1 can be connected to the pixel driving circuit PD through the first electrode lines AND.

For example, in the light emitting device part EDU, as illustrated in FIG. 11C, first electrode lines AND can be disposed on the upper and lower sides of the pixel driving circuit PD, respectively.

As illustrated in FIG. 11C, one first electrode line AND among the first electrode lines AND can connect the first electrodes CE1 of the light emitting devices ED adjacent to each other in the vertical direction among the light emitting devices ED.

In this case, a pixel circuit PC can be connected to each of the first electrode lines AND. However, the pixel circuit PC can be connected to at least two first electrode lines AND. In this case, the anode voltage can be sequentially supplied to at least two first electrode lines AND.

Hereinafter, the basic driving method of the display apparatus according to the present disclosure in the display period in which the image is displayed will be briefly described.

FIG. 11D is an exemplary diagram illustrating a light emitting signal applied to a display apparatus according to an implementation of the present disclosure, and FIG. 11E is an exemplary diagram illustrating a pixel circuit applied to a display apparatus according to an implementation of the present disclosure.

As described above, the pixel driving circuit PD can control the light emitting operation of the light emitting device ED by using the pulse width of the light emitting signal EM.

For example, as illustrated in FIG. 11D, the pixel driving circuit PD can adjust the pulse width of the light emitting signal EM, and thus, light corresponding to 1 Gray to 32 Gray can be output through the light emitting device ED.

The pixel driving circuit PD can supply a light emitting signal EM having a pulse width adjusted based on gray to a gate electrode of the light emitting transistor TEM.

In this case, a fixed light emitting current can be applied to the light emitting device ED through the light emitting transistor TEM, and thus, the light emitting device ED can output light.

For example, when eight light emitting devices ED are connected to one first electrode line AND, the eight light emitting devices ED can output light by constant current having the same current value.

In this case, in a typical organic light emitting display apparatus, the amount of current flowing to the light emitting device is different because the voltage applied to the gate electrode of the driving transistor varies from one light emitting device to another, and the time for which the current flows to the light emitting devices is the same.

However, in the display apparatus according to an implementation of the present disclosure, the amount of current flowing to the light emitting devices ED is the same, and the time for which the current flows is different for each light emitting device. That is, the time for which the current flows through the light emitting device can be adjusted by the pulse width of the light emitting signal (PWM) signal EM.

For example, the pixel circuit PC, as illustrated in FIGS. 4 and 11E, includes a driving transistor TDR and a light emitting transistor TEM, and is connected to light emitting devices. Reference numerals 1H, 2H, and 8H illustrated in FIG. 11E refer to light emitting devices ED provided in the first row 1H, the second row 2H, and the eighth row 8H illustrated in FIG. 11B.

A high potential voltage AVDD can be applied to the first electrode of the driving transistor TDR, a light emitting transistor TEM can be connected to the second electrode of the driving transistor TDR, and a reference voltage VREF or initialization voltage VINT can be applied to the gate electrode of the driving transistor TDR. The reference voltage VREF or the initialization voltage VINT can be a scan signal SC.

For example, a reference voltage VREF can be applied to the gate electrode of the driving transistor TDR through a switching means, or an initialization voltage VINT can be applied to the gate electrode of the driving transistor TDR through a voltage buffer (VB) and a switching means.

A driving transistor TDR can be connected to the first electrode of the light emitting transistor TEM, light emitting devices can be connected to the second electrode of the light emitting transistor TEM, and a light emitting signal EM can be applied to the gate electrode of the light emitting transistor TEM.

Hereinafter, a display period in which an image is displayed and a touch sensing period in which a touch is detected will be briefly described with reference to FIGS. 11F and 11G.

FIG. 11F is an exemplary diagram illustrating a touch sensing method in a display apparatus according to an implementation of the present disclosure, and FIG. 11G is an exemplary diagram illustrating a display period and a touch sensing period applied to a display apparatus according to an implementation of the present disclosure.

In the display apparatus according to an implementation of the present disclosure, the second electrodes CE2 can be used as a touch electrode TE, and this structure is referred to as an in-cell touch structure. Because a separate touch electrode is not provided in the display apparatus according to an implementation of the present disclosure, the thickness of the display panel can be reduced.

For example, when the cover member 120 is touched by the user, the first capacitance C1 between the second electrodes CE2 and the cover member 120 which are provided on the display panel 100 and the second capacitance C2 between the second electrodes CE2 and the signal lines can be changed, as illustrated in FIG. 11F.

The touch sensing signal generated by the change of the first capacitance C1 and the second capacitance C2 can be transmitted to the pixel driving circuit PD through the second electrodes CE2. In this case, the pixel driving circuit PD can be connected to the ground part GND.

The touch sensing signals transmitted to the pixel driving circuit PD can be transmitted to the display driver 200, and the display driver 200 can determine whether there is a touch on the touch electrode TE by using the touch sensing signals transmitted from the at least one pixel driving circuit PD.

One frame period (1Frame Period) can mean a period in which one image is displayed through the display panel 100. As illustrated in FIG. 11G, one frame period can include a display period DP and a touch sensing period TP. In one frame period, the touch sensing period TP and the display period DP can be different. For example, the touch sensing period TP can be shorter than the display period DP.

In one frame period, the touch sensing period TP and the display period DP can be repeated at least once. For example, as illustrated in FIG. 11G, in one frame period (1Frame period), the touch sensing period TP and the display period DP can be repeated four times. However, a display apparatus according to an implementation of the present disclosure is not limited thereto. Accordingly, the number of times that the touch sensing period TP and the display period DP are repeated in one frame period can be variously changed, and the touch sensing period TP and the display period DP can be repeated at interval of at least two frame periods.

The timing controller 300 can generate and transmit a touch synchronization signal Tsync to the display driver 200.

The display driver 200 can perform an operation for displaying an image depending on a touch synchronization signal Tsync or an operation for sensing a touch.

When a touch signal S1 indicating the touch sensing period TP is received among the touch synchronization signals Tsync that distinguishes the touch sensing period TP from the display period DP, the display driver 200 can transmit the touch enable pulse E1 constituting the touch enable signal Touch_EN to the sensing switch 430.

In the following description, the touch synchronization signal Tsync can include a touch signal S1 indicating the touch sensing period TP and a display signal S2 indicating the display period DP. When the touch signal S1 is received, the display driver 200 can perform an operation for sensing a touch, and when the display signal S2 is received, the display driver 200 can perform an operation for displaying an image.

In the following description, the touch enable signal Touch_EN can include a touch enable pulse E1 for turning on the sensing switch 430 and a touch enable off signal E2 for turning off the sensing switch 430.

When the touch enable pulse E1 is received, the sensing switch 430 can connect the power supply part 520 to the sensing part 440.

In this case, the sensing part 440 can be driven by power supplied from the power supply part 520 to supply a touch driving signal to the second electrodes CE2. Accordingly, the touch sensing signal received from the second electrodes CE2 can be transmitted to the display driver 200, and whether a touch has occurred can be determined by the display driver 200.

When the touch enable pulse E1 is not received, the sensing switch 430 can block the power supply part 520 from the sensing part 440. When the touch enable pulse E1 is not received, it means that the touch enable off signal E2 is received.

For example, when the touch enable off signal E2 is received, the sensing switch 430 can be turned off, and accordingly, power is not supplied to the sensing part 440.

Accordingly, the touch driving signal cannot be supplied from the sensing part 440 to the second electrodes CE2, and the touch sensing signal cannot be transmitted to the display driver 200. That is, when the touch enable off signal E2 is received, the touch sensing operation is not performed. Accordingly, power consumption of the sensing part 440 can be reduced.

The width of the touch enable pulse E1 can be the same as the width of the touch signal S1, or as illustrated in FIG. 11G, can be smaller than the width of the touch signal S1.

For example, the width of the touch enable pulse E1 can be equal to the width of the touch signal S1 during a normal touch sensing period, and the width of the touch enable pulse E1 can be smaller than the width of the touch signal S1 during a wake-up touch sensing period.

In the following description, the touch sensing period can include the normal touch sensing period and the wake-up touch sensing period.

The normal touch sensing period means a touch sensing period continued after it is determined that there is a touch, and the wake-up touch sensing period means a touch sensing period continued after it is determined that there is no touch. The wake-up touch sensing period can continue until a touch is detected.

For example, the touch sensing period can be the normal touch sensing period or the wake-up touch sensing period. That is, the normal touch sensing period and the wake-up touch sensing period do not occur simultaneously.

During the wake-up touch sensing period, as described above, the width of the touch enable pulse E1 can be smaller than the width of the touch signal S1, and accordingly, the driving time of the sensing part 440 can be reduced, and thus the power consumption of the sensing part 440 can be reduced.

During the normal touch sensing period, the width of the touch enable pulse E1 can be equal to the width of the touch signal S1, as described above. However, even during the normal touch sensing period, the sensing part 440 do not need to be driven during the period when the touch driving signal is not supplied to the second electrode CE2. Therefore, even during the normal touch sensing period, the width of the touch enable pulse E1 can be smaller than the width of the touch signal S1.

Hereinafter, various driving methods of a display apparatus according to an implementation of the present disclosure will be described.

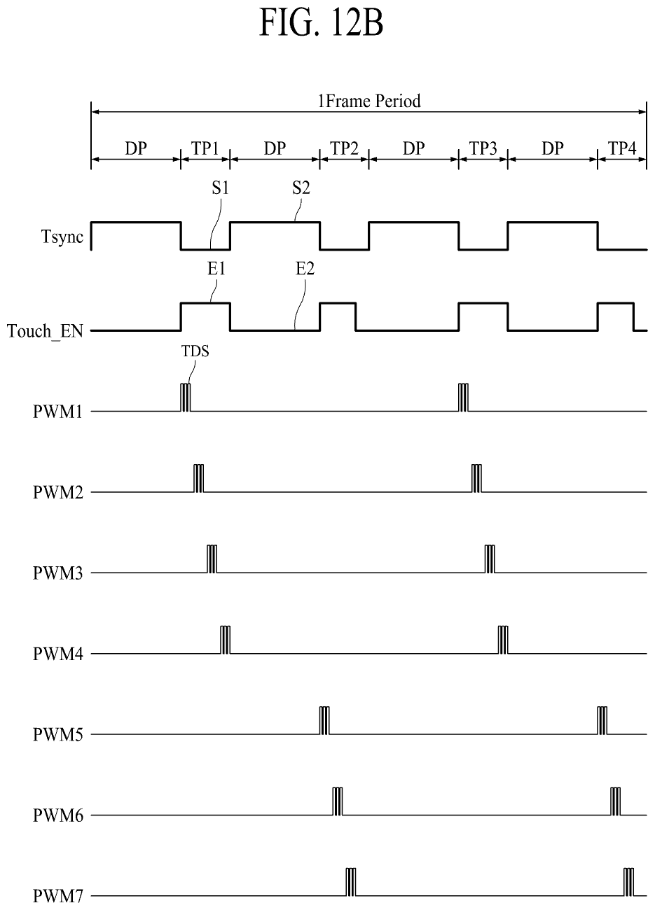

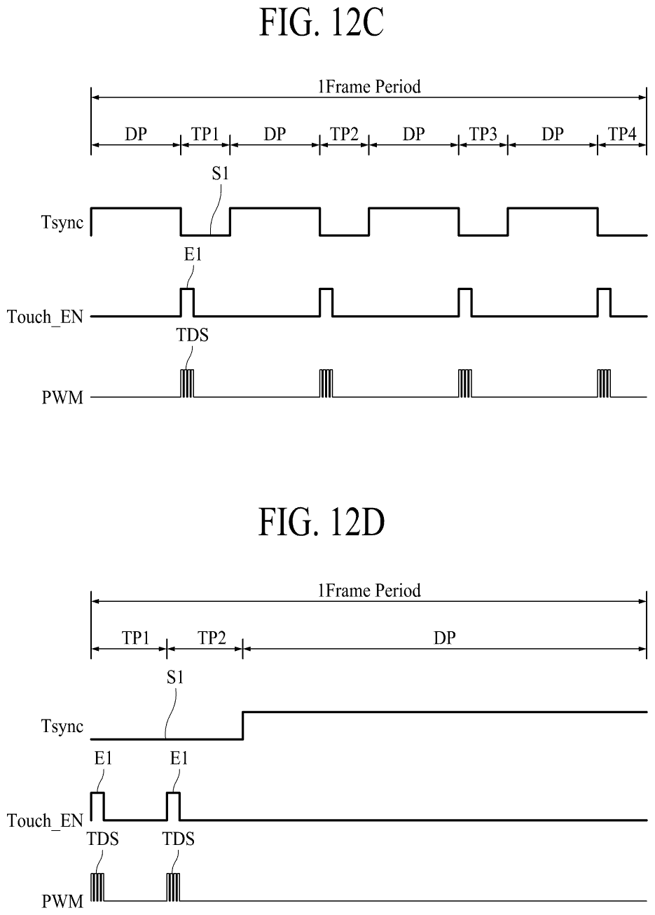

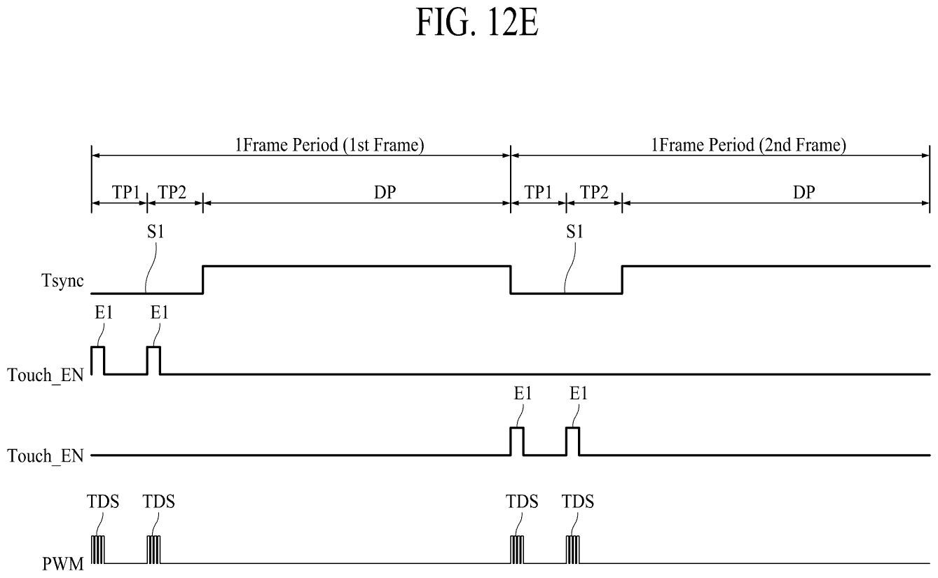

FIGS. 12A to 12E are exemplary diagrams illustrating various driving methods of a display apparatus according to an implementation of the present disclosure. In the following descriptions, details that are the same as or similar to those described with reference to FIGS. 1 to 11G are omitted or briefly described. In addition, hereinafter, a driving method during the touch sensing period will be described.

First of all, FIG. 12A shows a method of driving a display apparatus using a self-capacitance method, and in particular, a driving method in a normal touch sensing period.

As described above, the touch synchronization signal Tsync can include a touch signal S1 indicating the touch sensing period TP and a display signal S2 indication the display period DP.

When the touch signal S1 is received during the normal touch sensing period, the display driver can transmit the touch enable pulse E1 to the sensing switches 430. Accordingly, the sensing switches 430 can be turned on, power can be supplied to the sensing part 440, and the sensing part can be driven.

The normal touch sensing period refers to a touch sensing period that lasts after it is determined that there is a touch, and thus, there is a high possibility that the touch will be detected.

Therefore, the touch driving signals TDS need to be quickly supplied to the touch electrodes TE. The touch driving signals TDS can be pulse width modulation (PWM) signals.

For example, when the display panel 100 illustrated in FIG. 10 uses only the self-capacitance method, seven touch electrodes TE can be provided along the second direction Y. In the following description, horizontal lines including the seven touch electrodes TE are referred to as touch electrode rows. In this case, six touch electrodes TE can be provided in each of the seven touch electrode rows formed on the display panel 100 illustrated in FIG. 10.

When four touch sensing periods TP are included in one frame period, the sensing part 440 can supply touch driving signals TDS to touch electrodes TE provided in seven touch electrode rows for each touch sensing period TP.

However, the sensing part 440 can supply touch driving signals TDS to touch electrodes TE provided in four of seven touch electrode rows during a first touch sensing period TP1 among four touch sensing period TD, and the sensing part 440 can supply touch driving signals TDS to touch electrodes TE provided in the remaining three of the seven touch electrode rows during a second touch sensing period TP2 among four touch sensing periods TP.

During the first touch sensing period TP1, the sensing part 440 can simultaneously supply touch driving signals TDS to the touch electrodes TE provided in the four touch electrode rows, or can sequentially supply touch driving signals TDS to the four touch electrode rows.

The period in which the touch driving signals TDS are sequentially supplied to the three touch electrode rows in the second touch sensing period TP2 can be shorter than the period in which the touch driving signals TDS are sequentially supplied to the four touch electrode rows in the first touch sensing period TP1.

Moreover, when touch driving signals TDS are simultaneously supplied to touch electrodes TE provided in different touch electrode rows in each of the first touch sensing period TP1 and the second touch sensing period TP2, the period in which touch driving signals TDS are simultaneously supplied to four touch electrode rows in the first touch sensing period TP1 can be longer than the period in which touch driving signals TDS are simultaneously supplied to three touch electrode rows in the second touch sensing period TP2, in order to increase touch sensitivity.

In this case, the width of the touch enable pulse E1 supplied to the sensing switch 430 during the first touch sensing period TP1 can be equal to or less than the width of the touch signal S1.

In addition, the width of the touch enable pulse E1 supplied to the sensing switch 430 during the second touch sensing period TP2 can be smaller than the width of the touch enable pulse E1 supplied to the sensing switch 430 during the first touch sensing period TP1.

Therefore, power can be withheld from the sensing part 440 when the touch driving signals TDS are not supplied to the touch electrodes in the second touch sensing period TP2, and thus power consumption of the sensing part 440 can be reduced.

To provide an additional description, when the sensing part 440 does not need to be driven even during the normal touch sensing period, power supplied to the sensing part 440 can be blocked, and thus power consumption of the display apparatus including the sensing part 440 can be reduced.

Next, FIG. 12B illustrates a driving method of a display apparatus using a mutual-capacitance method, and in particular, a driving method during a normal touch sensing period.

In a display apparatus using the mutual-capacitance method, the touch driving signal TDS can be sequentially supplied to the first driving electrodes TX1 to the seventh driving electrodes TX7 illustrated in FIG. 10. For example, during a first touch sensing period TP1, the touch driving signals TDS can be sequentially supplied to the first driving electrodes TX1 to the fourth driving electrodes TX4, and during a second touch sensing period TP2, the touch driving signals TDS can be sequentially supplied to the fifth driving electrodes TX5 to the seventh driving electrodes TX7.

The period during which the touch driving signal TDS is sequentially supplied to the first driving electrode TX1 to the fourth driving electrode TX4 can be longer than the period during which the touch driving signal TDS is sequentially supplied to the fifth driving electrode TX5 to the seventh driving electrode TX7.

Accordingly, the width of the touch enable pulse E1 supplied to the sensing switch 430 during the first touch sensing period TP1 can be equal to or smaller than the width of the touch signal S1, and the width of the touch enable pulse E1 supplied to the sensing switch 430 during the second touch sensing period TP2 can be smaller than the width of the touch enable pulse E1 supplied to the sensing switch 430 during the first touch sensing period TP1.

Therefore, power can be withheld from the sensing part 440 when the touch driving signals TDS are not supplied to the touch electrodes in the second touch sensing period TP2, and thus power consumption of the sensing part 440 can be reduced.

In this case, the sub-receiving electrodes provided in the same touch electrode row as the driving electrode TX to which the touch driving signal TDS is supplied can be supplied with the same touch enable pulse E1 as the touch enable pulse E1 applied to the driving electrode TX to which the touch driving signal TDS is supplied.

Accordingly, the width of the touch enable pulse E1 supplied to the sensing switch 430 of the sub-receiving electrode during the first touch sensing period TP1 can be equal to or smaller than the width of the touch signal S1, and the width of the touch enable pulse E1 supplied to the sensing switch 430 of the sub-receiving electrode during the second touch sensing period TP2 can be smaller than the width of the touch enable pulse E1 supplied to the sensing switch 430 of the sub-receiving electrode during the first touch sensing period TP1.

Accordingly, power can be withheld from the sensing part 440 when the touch sensing signals are not received in the second touch sensing period TP2, and thus power consumption of the sensing part 440 can be reduced.

Next, FIG. 12C illustrates a driving method of a display apparatus using a self-capacitance method or a mutual-capacitance method, and in particular, a driving method during the wake-up touch sensing period.

The wake-up touch sensing period means a touch sensing period continued after it is determined that there is no touch, there is a high possibility that there is no touch during the wake-up touch sensing period.

Therefore, it is not necessary to quickly supply the touch driving signals TDS to the touch electrodes TE.

Therefore, during the wake-up touch sensing period, a touch can be detected on the touch electrodes TE provided in at least one of the seven touch electrode rows illustrated in FIG. 10.

For example, when the self-capacitance method is used, the touch driving signal TDS can be supplied to the touch electrodes TE provided in the first touch electrode row among the seven touch electrode rows illustrated in FIG. 10 during a first touch sensing period TP1, the touch driving signal TDS can be supplied to the touch electrodes TE provided in the second touch electrode row during a second touch sensing period TP2, and the touch driving signal TDS can be supplied to the touch electrodes TE provided in the third touch electrode row during a third touch sensing period TP3, and the touch driving signal TDS can be supplied to the touch electrodes TE provided in the fourth touch electrode row during a fourth touch sensing period TP4.

After that, in another one frame period, the touch driving signal TDS can be supplied to the touch electrodes TE provided in a fifth touch electrode row during a first touch sensing period TP1, the touch driving signal TDS can be supplied to the touch electrodes TE provided in the sixth touch electrode row during a second touch sensing period TP2, and the touch driving signal TDS can be supplied to the touch electrodes TE provided in the seventh touch electrode row during a third touch sensing period TP3. The touch driving signal TDS can be supplied to the touch electrodes TE provided in the first touch electrode row during a fourth touch sensing period TP4, but the touch driving signal is not supplied to the touch electrodes during the fourth touch sensing period TP4.

In this case, in two frame periods, a touch can be detected from the entire display panel 100. Here, the two frame periods mean a period in which one frame period is repeated twice.

However, as another example, the touch driving signal TDS can be supplied to the touch electrodes TE provided in the first touch electrode row and the second touch electrode row during a first touch sensing period TP1, the touch driving signal TDS can be supplied to the touch electrodes TE provided in the third touch electrode row and the fourth touch electrode rows during a second touch sensing period TP2, the touch driving signal TDS can be supplied to the touch electrodes TE provided in the fifth touch electrode row and the sixth touch electrode rows during a third touch sensing period TP3, and the touch driving signal TDS can be supplied to the touch electrodes TE provided in the seventh touch electrode row during a fourth touch sensing period TP4.

In this case, in one frame period, a touch can be detected on the entire display panel 100.

That is, in the wake-up touch sensing period, a period in which a touch is detected throughout the display panel 100 can be variously changed.

Also, the period in which the touch driving signal is supplied to the touch electrodes TE during the wake-up touch sensing period can be shorter than the period in which the touch driving signal is supplied to the touch electrodes TE during the normal touch sensing period.

Accordingly, the width of the touch enable pulse E1 during the wake-up touch sensing period can be smaller than the width of the touch enable pulse E1 during the normal touch sensing period illustrated in FIGS. 12a and 12b.

Accordingly, the power consumption of the sensing part 440 in the wake-up touch sensing period can be smaller than the power consumption of the sensing part 440 in the normal touch sensing period.

The description described above with reference to FIG. 12C can also be applied even when the mutual-capacitance method is used.

Therefore, in the display apparatus using the mutual-capacitance method, the power consumption of the sensing part 440 during the wake-up touch sensing period can be smaller than the power consumption of the sensing part 440 during the normal touch sensing period.

Next, FIG. 12D illustrates a driving method of a display apparatus using the self-capacitance method and the mutual-capacitance method, and particularly, a driving method in the wake-up touch sensing period. In the following descriptions, details that are the same as or similar to those described with reference to FIGS. 12A to 12C are omitted or briefly described.

For example, in FIG. 12C, when a touch is detected using a self-capacitance method in the first touch sensing period TP1 and the third touch sensing period TP3, and a touch is detected using a mutual-capacitance method in the second touch sensing period TP2 and the fourth touch sensing period TP4, the width of the touch enable pulse E1 in each of the first touch sensing period TP1 to the fourth touch sensing period TP4 can be smaller than the width of the touch enable pulse E1 in the normal touch sensing period illustrated in FIGS. 12A and 12B.

Therefore, in a display apparatus using the self-capacitance method and the mutual-capacitance method, the power consumption of the sensing part 440 during the wake-up touch sensing period can be smaller than the power consumption of the sensing part 440 during the normal touch sensing period.

Also, the power consumption of the sensing part 440 during the normal touch sensing period can be less than the power consumption of the sensing part 440 applied to the conventional display apparatus.

In a display apparatus using the self-capacitance method and the mutual-capacitance method, the touch sensing period TP using the self-capacitance method and the touch sensing period TP using the mutual-capacitance method can be continuous as illustrated in FIG. 12D, and in one frame period, the touch sensing period TP using the self-capacitance method and the touch sensing period TP using the mutual-capacitance method can occur only once.

In this case, a touch can be detected using a self-capacitance method in a first touch sensing period TP1, and a touch can be detected using a mutual-capacitance method in a second touch sensing period TP2.

In particular, while the touch signal S1 is supplied, a touch detection using the self-capacitance method and a touch detection using the mutual-capacitance method can be sequentially performed.

In this case, the sum of the width of the touch enable pulse E1 supplied to the sensing switch 430 during the first touch sensing period TP1 and the width of the touch enable pulse E1 supplied to the sensing switch 430 during the second touch sensing period TP2 can be smaller than the width of the touch signal S1. Also, the width of each of the touch enable pulses E1 can be set to be approximately equal to the period during which the touch driving signal TDS is substantially supplied to the touch electrodes TE.

This means that power is supplied to the sensing part 440 only during a period in which a touch is actually detected.

Therefore, according to a display apparatus according to the present disclosure, power consumption of the sensing part 440 can be reduced, and accordingly, power consumption of a display apparatus can be reduced.

Finally, FIG. 12E illustrates a driving method of another display apparatus using the self-capacitance method and the mutual-capacitance method, and in particular, a driving method during the wake-up touch sensing period.

In a display apparatus using the self-capacitance method and the mutual-capacitance method, the touch sensing period TP using the self-capacitance method and the touch sensing period TP using the mutual-capacitance method can be continuous as illustrated in FIGS. 12d and 12e, and in one frame period, the touch sensing period TP using the self-capacitance method and the touch sensing period TP using the mutual-capacitance method can occur only once.

In this case, a touch can be detected using the self-capacitance method in a first touch sensing period TP1 and a second touch sensing period TP2 continuously in one frame period (hereinafter simply referred to as a first frame), and a touch can be detected using the mutual-capacitance method in another one frame period (hereinafter simply referred to as the second frame) after the first frame.

For example, when the touch electrodes TE illustrated in FIG. 10 are divided into two groups along the first direction X, each of a first group and a second group can include touch electrodes TE provided in the form of 3×7 (horizontal×vertical).

In this case, a touch at the touch electrodes TE provided in the first group can be detected using the self-capacitance method during the first touch sensing period TP1 and the second touch sensing period TP2 of the first frame, and a touch at the touch electrodes TE provided in the second group can be detected using the mutual-capacitance method during the first touch sensing period TP1 and the second touch sensing period TP2 of the second frame.

In this case, the sum of the width of the touch enable pulse E1 supplied to the sensing switch 430 during the first touch sensing period TP1 of the first frame and the width of the touch enable pulse E1 supplied to the sensing switch 430 during the second touch sensing period TP2 of the first frame can be smaller than the width of the touch signal S1 of the first frame. Also, the width of each of the touch enable pulses E1 can be set to be approximately equal to the period in which the touch driving signal TDS is substantially supplied to the touch electrodes TE.

Moreover, the sum of the width of the touch enable pulse E1 supplied to the sensing switch 430 during the first touch sensing period TP1 of the second frame and the width of the touch enable pulse E1 supplied to the sensing switch 430 during the second touch sensing period TP2 of the second frame can be smaller than the width of the touch signal S1 of the second frame. Also, the width of each of the touch enable pulses E1 can be set to be approximately equal to the period in which the touch driving signal TDS is substantially supplied to the touch electrodes TE.

This means that power is supplied to the sensing part 440 only during a period in which a touch is actually detected.

Therefore, according to ae display apparatus according to the present disclosure, power consumption of the sensing part 440 can be reduced, and accordingly, power consumption of a display apparatus can be reduced.

To provide an additional description, in a display apparatus according to an implementation of the present disclosure, as illustrated in FIGS. 12D and 12E, when the touch signal S1 is received, the display driver 200 can sequentially transmit a first enable pulse E1 and a second enable pulse E1 to the sensing switch 430.

In this case, when the first enable pulse E1 is received, the sensing part 440 can supply the touch driving signal TDS to the second electrodes CE2, convert the analog-type touch sensing signal received from the second electrodes CE2 into a digital-type touch sensing signal, and transmit the digital-type touch sensing signal to the display driver 200. For example, as described with reference to FIG. 12D, a touch can be detected in the first touch sensing period TP1 by using the self-capacitance method.

After that, when the second enable pulse E1 is received, the sensing part 440 can supply a touch driving signal TDS to the second electrodes CE2, or can convert an analog-type touch sensing signal received from the second electrodes CE2 into a digital-type touch sensing signal, and transmit the digital-type touch sensing signal to the display driver 200. For example, as described with reference to FIG. 12D, a touch can be detected in the second touch sensing period TP2 by using the mutual-capacitance method.

As described above, in a display apparatus according to an implementation of the present disclosure, the width of the touch enable pulse E1 can be reduced or minimized in the wake-up touch sensing period, the time for which the sensing part 440 are driven can be reduced or minimized, and thus the power consumption of the sensing part 440 can be reduced or minimized. The width of the touch enable pulse E1 can be smaller than the width of the touch signal S1 not only in the wake-up touch sensing period but also in the normal touch sensing period, and accordingly, the power consumption of the sensing part 440 can be reduced in the normal touch sensing period.

Also, in a display apparatus according to an implementation of the present disclosure, touch electrodes provided along the first direction X or the second direction Y of the display panel 100 can be divided into groups, and a touch can be detected by sequentially driving groups. In this case, groups can be set in various shapes and numbers, and accordingly, a period or ratio in which a touch is detected on the display panel 100 can be variously changed.

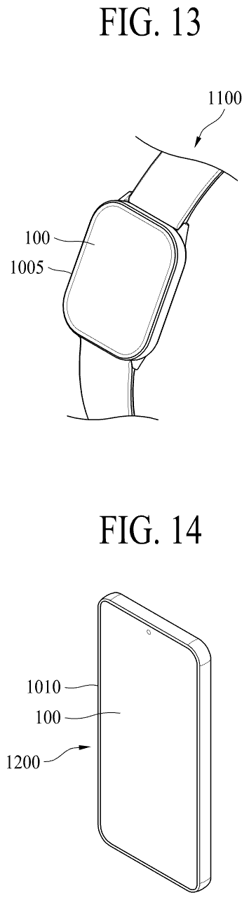

FIGS. 13 to 16 are diagrams illustrating electronic devices to which a display apparatus according to implementations of the present disclosure is applied.

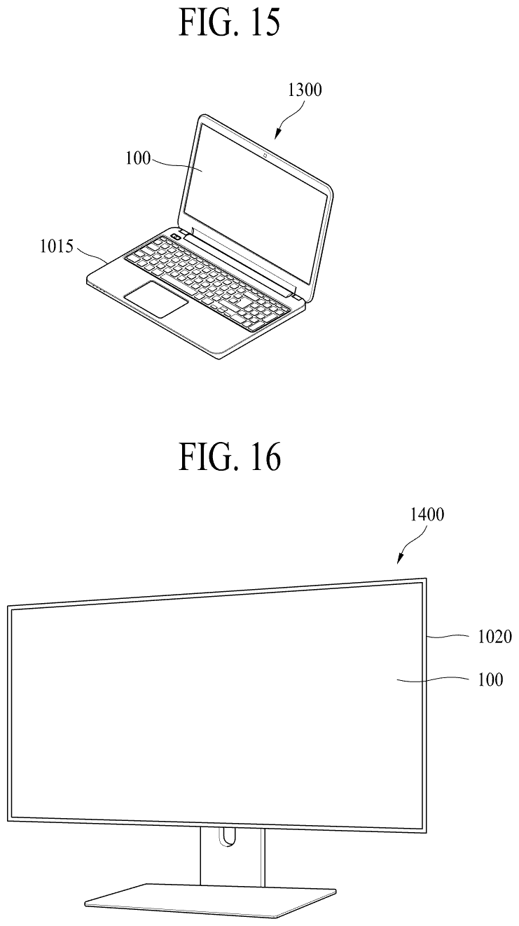

Referring to FIGS. 13 to 16, the display apparatus according to implementations of the present disclosure can be included in various electronic devices. For example, various electronic devices can be a wearable device 1100 as illustrated in FIG. 13, a mobile device 1200 as illustrated in FIG. 14, a laptop 1300 as illustrated in FIG. 15, or a monitor or TV 1400 as illustrated in FIG. 16, but implementations of the present disclosure are not limited thereto.

Each of the wearable device 1100, the mobile device 1200, the laptop 1300, and the monitor or TV 1400 can include a case part 1005, 1010, 1015, and 1020, and a display panel 100 and a display apparatus 1000 according to implementations of the present disclosure described above.

For example, the display apparatus according to an implementation of the present disclosure can be applied to a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), PDA(personal digital assistant), an MP3 player, a mobile medical device, a desktop personal computer (PC), a laptop PC, a netbook computer, a workstation, a navigation, a vehicle display, a theater display, a television, a wall paper device, a signage device, a game device, a laptop, a game device, a monitor, a camera, a camcorder or a home appliance.

The features of the display apparatus according to an implementation of the present disclosure are briefly summarized as follows.

A display apparatus according to an implementation of the present disclosure comprises a substrate including a display area and a non-display area, a pixel driving circuit provided in the display area, first electrodes connected to the pixel driving circuit, light emitting devices provided on the first electrodes, and second electrodes provided on the light emitting devices, wherein the pixel driving circuit comprises: a sensing part configured to supply a cathode voltage or a touch driving signal to the second electrodes; and a sensing switch configured to, in response to a touch enable signal, transmit power from a power part to the sensing part or block power transmitted from the power part.

At least two second electrodes connected to the pixel driving circuit are used as one touch electrode.

Each of the at least two second electrodes extends along a first direction of the substrate, and the at least two second electrodes are provided along a second direction different from the first direction.

When a cathode voltage is supplied to any one of the at least two second electrodes, light is emitted from light emitting devices connected to the second electrode to which the cathode voltage is supplied.

When the at least two second electrodes are used as one touch electrode, a touch driving signal is simultaneously supplied to the at least two second electrodes.

The pixel driving circuit further comprises a control switching part configured to supply a cathode voltage to the second electrodes during a display period, and to connect the sensing part to the second electrodes during a touch sensing period.

The pixel driving circuit further comprises a sub-pixel driving part configured to supply anode voltages to the first electrodes.

A display apparatus according to an implementation of the present disclosure further comprises a display driver configured to transmit a touch enable signal to the sensing switch.

The display driver transmits a touch enable pulse, which constitutes the touch enable signal, to the sensing switch when a touch signal indicating a touch sensing period among a touch synchronization signal is received, and the touch synchronization signal distinguishes a touch sensing period from a display period.

When the touch enable pulse is received, the sensing switch connects the power part to the sensing part.

The sensing part is driven by power supplied from the power part and supplies the touch driving signal to the second electrodes.

When the touch enable pulse is not received, the sensing switch disconnects the power part from the sensing part.

A width of the touch enable pulse is less than or equal to a width of the touch signal.

When the touch signal is received, the display driver sequentially transmits a first enable pulse and a second enable pulse to the sensing switch.

When the first enable pulse is received, the sensing part supplies a touch driving signal to the second electrodes, converts an analog-type touch sensing signal received from the second electrodes into a digital-type touch sensing signal, and transmits the digital-type touch sensing signal to the display driver, and when the second enable pulse is received, the sensing part supplies a touch driving signal to the second electrodes or converts an analog-type touch sensing signal received from the second electrodes into a digital-type touch sensing signal and transmits the digital-type touch sensing signal to the display driver.

The touch sensing period includes a normal touch sensing period that continues after a touch is determined to be present and a wake-up touch sensing period that continues after a touch is determined to be absent, and the display driver transmits the touch enable pulse to the sensing switch during each of the normal touch sensing period and the wake-up touch sensing period.

According to the present disclosure, power supplied to the sensing part configured to output the touch driving signal can be blocked during a period in which the touch driving signal is not output to the touch electrode in the touch sensing period. Accordingly, power consumption of the display apparatus can be reduced.

Accordingly, according to the present disclosure, a display apparatus having low power characteristics can be provided, and accordingly, a display apparatus capable of implementing an Environment/Social/Governance (ESG) can be provided.

The above-described feature, structure, and effect of the present disclosure are included in at least one implementation of the present disclosure, but are not limited to only one embodiment. Furthermore, the feature, structure, and effect described in at least one implementation of the present disclosure can be implemented through combination or modification of other implementations by those skilled in the art. Therefore, content associated with the combination and modification should be construed as being within the scope of the present disclosure.

It will be apparent to those skilled in the art that various modifications and variations can be made in the present disclosure without departing from the technical idea or scope of the disclosures. Thus, it is intended that the present disclosure covers the modifications and variations of this disclosure provided they come within the scope of the present disclosure.

What is claimed is:

1. A display apparatus comprising:
a substrate including a display area and a non-display area;
a pixel driving circuit provided in the display area;
one or more first electrodes connected to the pixel driving circuit;
one or more light emitting devices provided on the one or more first electrodes; and
a plurality of second electrodes provided on the light emitting devices,
wherein the pixel driving circuit comprises:
a sensing circuit configured to supply a cathode voltage or a touch driving signal to the plurality of second electrodes; and
a sensing switch configured to, in response to a touch enable signal, transmit power from a power circuit to the sensing circuit or block power transmitted from the power circuit.

2. The display apparatus of claim 1, wherein the display apparatus is configured to use at least two second electrodes among the plurality of second electrodes connected to the pixel driving circuit as one touch electrode.

3. The display apparatus of claim 2, wherein each of the at least two second electrodes extends along a first direction of the substrate, and
the at least two second electrodes are provided along a second direction of the substrate that is different from the first direction of the substrate.

4. The display apparatus of claim 3, wherein, for each second electrode of the at least two second electrodes, the display apparatus is configured to emit light from the light emitting devices connected to the second electrode when a cathode voltage is supplied to the second electrodes.

5. The display apparatus of claim 3, wherein the display apparatus is configured to simultaneously supply a touch driving signal to the at least two second electrodes when the display apparatus uses the at least two second electrodes as one touch electrode.

6. The display apparatus of claim 1, wherein the pixel driving circuit further comprises a control switching part configured to supply a cathode voltage to the plurality of second electrodes during a display period and to connect the sensing circuit to the plurality of second electrodes during a touch sensing period.

7. The display apparatus of claim 1, wherein the pixel driving circuit further comprises a sub-pixel driving part configured to supply anode voltages to the one or more first electrodes.

8. The display apparatus of claim 1, further comprising a display driver configured to transmit a touch enable signal to the sensing switch.

9. The display apparatus of claim 8, wherein the display driver is configured to transmit a touch enable pulse, which constitutes the touch enable signal, to the sensing switch when the display driver receives a touch synchronization signal that includes a touch signal indicating a touch sensing period, and
the touch synchronization signal distinguishes the touch sensing period from a display period.

10. The display apparatus of claim 9, wherein the sensing switch is configured to connect the power circuit to the sensing circuit when the sensing switch receives the touch enable pulse.

11. The display apparatus of claim 10, wherein the sensing circuit is configured to be driven by power supplied from the power circuit and to supply the touch driving signal to the plurality of second electrodes.

12. The display apparatus of claim 10, wherein the sensing switch is configured to disconnect the power circuit from the sensing circuit when the sensing switch does not receive the touch enable pulse.

13. The display apparatus of claim 9, wherein a width of the touch enable pulse is less than or equal to a width of the touch signal.

14. The display apparatus of claim 9, wherein the display driver is configured to sequentially transmit a first enable pulse and a second enable pulse to the sensing switch when the display driver receives the touch synchronization signal that includes the touch signal indicating the touch sensing period.

15. The display apparatus of claim 14, wherein:
the sensing circuit is configured to, in response to receiving the first enable pulse, supply the touch driving signal to the plurality of second electrodes, convert an analog touch sensing signal received from the plurality of second electrodes into a digital touch sensing signal, and transmit the digital touch sensing signal to the display driver, and
the sensing circuit is configured to, in response to receiving the second enable pulse, (i) supply the touch driving signal to the plurality of second electrodes or (ii) convert an analog touch sensing signal received from the plurality of second electrodes into a digital touch sensing signal and transmit the digital touch sensing signal to the display driver.

16. The display apparatus of claim 9, wherein the touch sensing period includes a normal touch sensing period that continues after a touch is determined to be present and a wake-up touch sensing period that continues after a touch is determined to be absent, and
the display driver is configured to transmit the touch enable pulse to the sensing switch during each of the normal touch sensing period and the wake-up touch sensing period.
